(19) United States
(12) Patent Application Publication
(10) Pub. No.: US 2026/0173530 A1
(43) Pub. Date: Jun. 18, 2026

(54) ARRAY SUBSTRATE AND DISPLAY DEVICE

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(72) Inventors: Ran ZHANG, Beijing (CN); Yongxian XIE, Beijing (CN); Zhixiang ZOU, Beijing (CN); Liang LIN, Beijing (CN); Xiaoye MA, Beijing (CN); Yongcan WANG, Beijing (CN); Zhangtao WANG, Beijing (CN); Hui GUO, Beijing (CN); Zhiwei DING, Beijing (CN)

(73) Assignees: HEFEI XINSHENG OPTOELECTRONICS TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/850,120

(22) PCT Filed: Oct. 18, 2023
(86) PCT No.: PCT/CN2023/125100

§ 371 Date: Sep. 24, 2024

(51) Int. Cl. H10D 86/40; H10D 30/67; H10D 86/60

(52) U.S. Cl. CPC H10D 86/441; H10D 30/6736; H10D 86/60

(57) ABSTRACT

An array substrate includes a plurality of first wiring lines and a plurality of second wiring lines arranged on a base substrate, the first wiring lines and the second wiring lines intersect each other to define a plurality of pixel areas, each of the pixel areas comprises a transistor, a first electrode, a second electrode, a first via hole and a second via hole; an orthographic projection of the first via hole on the base substrate at least partially overlaps an orthographic projection of the first electrode on the base substrate, and an orthographic projection of the second via hole on the base substrate at least partially overlaps the orthographic projection of the first electrode on the base substrate; the orthographic projection of the first via hole on the base substrate does not overlap an orthographic projection of the second electrode on the base substrate.

### TECHNICAL FIELD

The present disclosure relates to the field of display technology, in particular to an array substrate and a display device.

### BACKGROUND

In the existing oxide Back-channel etch (BCE) process, since the gate insulation layer is located between the source-drain metal layer and the gate metal layer, and since both the source-drain metal layer and the gate metal layer are metal layers, the thickness of the gate insulation layer cannot be further reduced at the current mass production level, otherwise the risk of electrostatic discharge (ESD) between the gate metal layer and the source-drain metal layer will increase. The on-state current of the transistor is inversely proportional to the thickness of the gate insulation layer. The thicker the gate insulation layer is, the smaller the on-state current of the transistor is. Therefore, the on-state current of the transistor with the BCE structure cannot be further increased due to the limitation of the thickness of the gate insulation layer.

### SUMMARY

In one aspect, the present disclosure provides in some embodiments an array substrate, comprising a plurality of first wiring lines and a plurality of second wiring lines arranged on a base substrate, wherein the first wiring lines and the second wiring lines intersect each other to define a plurality of pixel areas, each of the pixel areas comprises a transistor, a first electrode, a second electrode, a first via hole and a second via hole; an orthographic projection of the first via hole on the base substrate at least partially overlaps an orthographic projection of the first electrode on the base substrate, and an orthographic projection of the second via hole on the base substrate at least partially overlaps the orthographic projection of the first electrode on the base substrate; the orthographic projection of the first via hole on the base substrate does not overlap an orthographic projection of the second electrode on the base substrate, and the orthographic projection of the second via hole on the base substrate does not overlap the orthographic projection of the second electrode on the base substrate.

Optionally, the first via hole and the second via hole are located in a same pixel area; another pixel area adjacent to the pixel area includes a third via hole; the orthographic projection of the second via hole on the base substrate and an orthographic projection of the third via hole on the base substrate are located on opposite sides of an orthographic projection of the first wiring line on the base substrate.

Optionally, the transistor comprises an active pattern, the orthographic projection of the second via hole on the base substrate at least partially overlaps an orthographic projection of a first conductor portion included in the active pattern on the base substrate; the second via hole is configured to electrically connect the first electrode of the transistor to the first conductor portion of the active pattern; a part of the first electrode falls into the first via hole, and the first via hole is configured to electrically connect the first electrode and the first conductor portion included in the active pattern.

Optionally, an orthographic projection of the third via on the base substrate at least partially overlaps an orthographic projection of a second conductor portion included in the active pattern on the base substrate; the third via hole is configured to electrically connect the second electrode of the transistor to the second conductor portion of the active pattern.

Optionally, along a first direction, a minimum distance between the orthographic projection of the first via hole on the base substrate and the orthographic projection of the first wiring line on the base substrate is smaller than a minimum distance between the orthographic projection of the second via hole on the base substrate and the orthographic projection of the first wiring line on the base substrate.

Optionally, the active pattern is in a dumbbell shape; and an angle between the orthographic projection of the active pattern on the base substrate and the orthographic projection of the first wiring line on the base substrate is greater than or equal to 85 degrees and less than or equal to 95 degrees.

Optionally, the second wiring line includes a second wiring line body, a first auxiliary portion, and a second auxiliary portion; the first auxiliary portion is electrically connected to the second wiring line body, and the second auxiliary portion is in a floating state; the first auxiliary portion is electrically connected to the second conductor portion included in the active pattern, and the second auxiliary portion is electrically connected to the first electrode.

Optionally, the array substrate includes 3a second wiring lines and 2a third wiring lines; a is a positive integer, two third wiring lines correspond to three second wiring lines, and the orthographic projection of the third wiring lines on the base substrate at least partially overlaps an orthographic projection of one of the three second wiring lines on the base substrate.

Optionally, the array substrate includes 3a second wiring lines and a third wiring lines; a is a positive integer; one of the third wiring lines corresponds to three second wiring lines, and an orthographic projection of the third wiring line on the base substrate at least partially overlaps an orthographic projection of one of the three second wiring lines on the base substrate.

Optionally, the array substrate further comprises a third wiring line; the third wiring line includes a signal line body portion and a connection portion electrically connected to each other; an orthographic projection of the connection portion on the base substrate at least partially overlaps the orthographic projection of the second via hole on the base substrate.

Optionally, the array substrate further includes a light shielding pattern; the light shielding pattern and the third wiring line are arranged in different layers; an orthographic projection of the connection portion on the base substrate at least partially overlaps an orthographic projection of the light shielding pattern on the base substrate.

Optionally, the array substrate further comprises a light shielding pattern; an orthographic projection of the light shielding pattern on the base substrate covers an orthographic projection of a conductor portion of an active pattern of the transistor on the base substrate.

Optionally, the array substrate includes a first metal layer, a second metal layer, a semiconductor layer and a first insulating layer, the transistor comprises an active pattern, a first gate electrode, a first electrode and a second electrode; the first gate electrode is formed on the first metal layer, the first electrode and the second electrode are formed on the second metal layer, and the active pattern is located in the semiconductor layer; the first insulating layer is arranged between the first metal layer and the semiconductor layer; a thickness of the first insulating layer is less than a first thickness threshold; the first thickness threshold is greater than or equal to 800 angstroms and less than or equal to 2000 angstroms; the first metal layer is arranged on a side of the semiconductor layer away from the base substrate.

Optionally, the thickness of the first insulating layer is greater than or equal to 500 angstroms and less than or equal to 2000 angstroms.

Optionally, the active pattern includes a semiconductor portion; the semiconductor portion includes a first semiconductor portion and a second semiconductor portion which are stacked; the first semiconductor portion is arranged between the second semiconductor portion and the base substrate, and the first semiconductor portion and the second semiconductor portion are made of semiconductor materials with different carrier mobilities.

Optionally, the array substrate further comprises a third metal layer and a second insulating layer; the third metal layer is arranged between the semiconductor layer and the base substrate, and the second insulating layer is arranged between the semiconductor layer and the third metal layer; the third metal layer includes a light shielding pattern, and an orthographic projection of the light shielding pattern on the base substrate covers an orthographic projection of a semiconductor portion in the active pattern on the base substrate.

Optionally, the active pattern extends along a first direction; a farthest distance between an edge of the orthographic projection of the light shielding pattern on the base substrate and an edge of the orthographic projection of the active pattern on the base substrate along a second direction is greater than a first distance threshold; the first distance threshold is greater than or equal to 4 μm; and the first direction intersects with the second direction.

Optionally, the light shielding pattern is multiplexed as a second gate electrode of the switch transistor.

Optionally, the array substrate further comprises a fourth metal layer; the first electrode is formed on the fourth metal layer; the fourth metal layer is arranged on a side of the second metal layer away from the base substrate; the first electrode is electrically connected to the second electrode of the transistor through a first via hole; an area of an orthographic projection of the first via hole on the base substrate is greater than or equal to 6 μm×7 μm and less than or equal to 8 μm×10 μm.

Optionally, the array substrate further includes a fifth metal layer; the second electrode is formed on the fifth metal layer; the fifth metal layer is arranged between the fourth metal layer and the second metal layer; a shortest distance between the orthographic projection of the second electrode on the base substrate and the edge of the orthographic projection of the first via hole on the base substrate is greater than a second distance threshold; the second distance threshold is greater than 2 μm.

Optionally, the shortest distance between the orthographic projection of the first electrode on the base substrate and an edge of the orthographic projection of the first via hole on the base substrate is greater than a third distance threshold; the third distance threshold is greater than or equal to 1.6 μm.

Optionally, the array substrate further comprises a fifth metal layer and a sixth metal layer, the fifth metal layer is arranged on a side of the second metal layer away from the base substrate, and the sixth metal layer is arranged on a side of the fifth metal layer away from the base substrate; the array substrate comprises a third wiring line; the third wiring line is formed on the sixth metal layer, and the second electrode is formed on the fifth metal layer; the array substrate further includes a fourth metal layer, a third insulating layer arranged between the sixth metal layer and the fifth metal layer, and a fourth insulating layer arranged between the sixth metal layer and the fourth metal layer; the fourth metal layer is arranged on a side of the sixth metal layer away from the base substrate; the array substrate comprises a first conductive pattern formed on the fourth metal layer; the first conductive pattern is electrically connected to the third wiring line through the fourth via hole, and the first conductive pattern is electrically connected to the second electrode through the fourth via hole and the fifth via hole, so that the third wiring line is electrically connected to the second electrode; the fourth via hole is a via hole penetrating the fourth insulating layer, and the fifth via hole is a via hole penetrating the third insulating layer; an area of an orthographic projection of the fourth via hole on the base substrate is greater than or equal to 3 μm×6 μm and less than or equal to 5 μm×8 μm.

Optionally, the array substrate includes a sixth metal layer, the array substrate includes a third wiring line, and the third wiring line is formed in the sixth metal layer; the third wiring line includes a signal line body portion and a connection portion that are interconnected; the orthographic projection of the connection portion on the base substrate covers an orthographic projection of a spacer on the base substrate, and the connection portion is configured to support the spacer; the array substrate is included in a display device, and the display device includes a color filter substrate, the spacer is arranged between the color filter substrate and the array substrate.

Optionally, the array substrate further includes a driving module arranged on the base substrate; wherein the driving module is arranged in a peripheral area; the driving module includes a plurality of stages of driving circuits; the driving circuit is configured to provide a driving signal for the pixel circuit; the driving circuit includes an input circuit, a reset circuit and a first node control circuit; the input circuit is electrically connected to an input control terminal, an input terminal and a first node respectively, and is configured to write an input signal provided by the input terminal into the first node under the control of an input control signal provided by the input control terminal; the reset circuit is electrically connected to a reset line, the first node and a first voltage line respectively, and is configured to control the connection between the first node and the first voltage line under the control of a reset signal provided by the reset line; the first node control circuit is electrically connected to a first second node, a second second node, a second voltage line and the first node, respectively, and is configured to control the connection between the first node and the second voltage line under the control of a potential of the first second node, and to control the connection between the first node and the second voltage line under the control of a potential of the second second node.

Optionally, the driving circuit further comprises a frame reset circuit; the frame reset circuit is electrically connected to a frame reset line, the first node and the second voltage line respectively, and is configured to control the connection between the first node and the second voltage line under the control of a frame reset signal provided by the frame reset line.

Optionally, the input circuit comprises a first transistor and a second transistor; a gate electrode of the first transistor and a gate electrode of the second transistor are electrically connected to the input control terminal, a first electrode of the first transistor is electrically connected to the input terminal, and a second electrode of the first transistor is electrically connected to the control node; a first electrode of the second transistor is electrically connected to the control node, and a second electrode of the second transistor is electrically connected to the first node.

Optionally, the driving circuit further comprises a control circuit; the control circuit is electrically connected to the control node, the first node and the third voltage line respectively, and is configured to control the connection between the control node and the third voltage line under the control of the potential of the first node.

Optionally, the input terminal and the input control terminal are a same signal terminal, and the input terminal is adjacent previous n stages of carry signal output terminals; or, the input terminal is the adjacent previous nth stages of the carry signal output terminals, and the input control terminal is the adjacent previous n stages of the driving signal output terminals; n is a positive integer.

Optionally, the reset circuit includes a third transistor and a fourth transistor, and the first node control circuit includes a fifth transistor, a sixth transistor, a seventh transistor and an eighth transistor; a gate electrode of the third transistor and a gate electrode of the fourth transistor are both electrically connected to the reset line, a first electrode of the third transistor is electrically connected to the first node, a second electrode of the third transistor is electrically connected to a first electrode of the fourth transistor, a second electrode of the third transistor is electrically connected to the control node; a second electrode of the fourth transistor is electrically connected to the first voltage line; a gate electrode of the fifth transistor and a gate electrode of the sixth transistor are both electrically connected to the first second node, a first electrode of the fifth transistor is electrically connected to the first node, a second electrode of the fifth transistor is electrically connected to a first electrode of the sixth transistor; a second electrode of the fifth transistor is electrically connected to the control node; a second electrode of the sixth transistor is electrically connected to the second voltage line; a gate electrode of the seventh transistor and a gate electrode of the eighth transistor are both electrically connected to the second second node, a first electrode of the seventh transistor is electrically connected to the first node, a second electrode of the seventh transistor is electrically connected to a first electrode of the eighth transistor; a second electrode of the seventh transistor is electrically connected to the control node; a second electrode of the eighth transistor is electrically connected to the second voltage line.

Optionally, the frame reset circuit comprises a ninth transistor and a tenth transistor; a gate electrode of the ninth transistor is electrically connected to the frame reset line, a first electrode of the ninth transistor is electrically connected to the first node, a second electrode of the ninth transistor is electrically connected to a first electrode of the tenth transistor; a second electrode of the ninth transistor is electrically connected to the control node; a second electrode of the tenth transistor is electrically connected to the second voltage line.

Optionally, the driving circuit further includes a storage capacitor and a driving signal output terminal; a first electrode plate of the storage capacitor is electrically connected to the first node, and a second electrode plate of the storage capacitor is electrically connected to the driving signal output terminal.

Optionally, the array substrate further comprises a third metal layer and a second insulating layer; the third metal layer is arranged on a side of the semiconductor layer close to the base substrate, and the second insulating layer is arranged between the semiconductor layer and the third metal layer; the first electrode plate is formed on the first metal layer, and the second electrode plate includes a first electrode plate portion and a second electrode plate portion electrically connected to each other; the first electrode plate portion is formed on the second metal layer, and the second electrode plate portion is formed on the third metal layer, an orthographic projection of the first electrode plate on the base substrate, an orthographic projection of the first electrode plate portion on the base substrate, and an orthographic projection of the second electrode plate portion on the base substrate at least partially overlap.

Optionally, the first electrode plate includes a first first electrode plate portion, a second first electrode plate portion and a third first electrode plate portion; the first electrode portion includes a first second electrode portion, a second second electrode portion and a third second electrode portion electrically connected to each other; the second electrode portion includes a first third electrode portion, a second third electrode portion and a third third electrode portion electrically connected to each other, the first first electrode plate portion, the second first electrode plate portion and the third first electrode plate portion are all formed in the first metal layer, the first second electrode plate portion, the second second electrode plate portion and the third second electrode plate portion are all formed in the second metal layer, and the first third electrode plate portion, the second third electrode plate portion and the third third electrode plate portion are all formed in the third metal layer, an orthographic projection of the first first electrode plate portion on the base substrate, an orthographic projection of the first second electrode plate portion on the base substrate and an orthographic projection of the first third electrode plate portion on the base substrate at least partially overlap; an orthographic projection of the second first electrode portion on the base substrate, an orthographic projection of the second second electrode portion on the base substrate and an orthographic projection of the second third electrode portion on the base substrate at least partially overlap; an orthographic projection of the third first electrode plate portion on the base substrate, an orthographic projection of the third second electrode plate portion on the base substrate, and an orthographic projection of the third third electrode plate portion on the base substrate at least partially overlap.

Optionally, the driving circuit includes a driving output circuit and a carry output circuit; the driving output circuit is configured to control the output of the driving signal under the control of the potential of the first node; the carry output circuit is configured to control the output of the carry signal under the control of the potential of the first node; an orthographic projection of an active pattern of a transistor included in the driving output circuit on the base substrate and an orthographic projection of the first first electrode portion on the base substrate are arranged along the first direction; an active pattern of a transistor included in the carry output circuit is arranged on a side of the active pattern of the transistor included in the driving output circuit close to the display area; an orthographic projection of the second first electrode portion on the base substrate is arranged on a side of the orthographic projection of the active pattern of the transistor included in the carry output circuit on the base substrate close to the display area; an orthographic projection of the third first electrode portion on the base substrate and the active pattern of the transistor included in the first node control circuit are arranged along the first direction.

Optionally, the peripheral area includes a fan-out area and a gating transistor arrangement area arranged between the fan-out area and the display area; the array substrate comprises M gating control lines and a gating part arranged in the gating transistor arrangement area; the gating part comprises a plurality of gating portions; M is an integer greater than 1; the gating portion includes a plurality of gating transistors; gate electrodes of the plurality of gating transistors are electrically connected to corresponding gating control lines, first electrodes of the plurality of gating transistors are electrically connected to corresponding data voltage supply lines, and second electrodes of the plurality of gating transistors are electrically connected to corresponding data lines.

Optionally, the peripheral area further includes an integrated circuit arrangement area arranged in the fan-out area away from the display area; the array substrate comprises a driving integrated circuit arranged in the integrated circuit arrangement area and a plurality of gating control signal supply lines; an mth gating control signal supply line is electrically connected to the driving integrated circuit and an mth gating control line respectively, and is configured to receive an mth gating control signal from the driving integrated circuit and provide the mth gating control signal to the mth gating control line; m is a positive integer less than or equal to M.

Optionally, the peripheral area further includes an integrated circuit arrangement area arranged in the fan-out area away from the display area; the array substrate includes a driving integrated circuit arranged in the integrated circuit arrangement area; the array substrate includes a touch signal line arranged in the display area; the data voltage supply line is electrically connected to the driving integrated circuit through a first connection line arranged in the fan-out area, and is configured to receive the data voltage provided by the driving integrated circuit; the touch signal line is electrically connected to the driving integrated circuit via a second connection line arranged in the fan-out area, and is configured to receive a touch sensing signal provided by the driving integrated circuit.

Optionally, a part of the first connection lines are formed in the first metal layer, and another part of the first connection lines are formed in the second metal layer.

Optionally, the array substrate further includes a third metal layer; the third metal layer is arranged on a side of the semiconductor layer close to the base substrate; a part of the first connection line are formed in the first metal layer, another part of the first connection lines are formed in the second metal layer, and another part of the first connection lines are formed in the third metal layer.

Optionally, in the gating transistor arrangement area; the array substrate further comprises a third metal layer; the third metal layer is arranged on a side of the semiconductor layer close to the base substrate; in the gating transistor arrangement area, the conductive pattern on the third metal layer is in a floating state.

Optionally, the array substrate further includes a touch signal line; the touch signal line is formed on the second metal layer; the array substrate further includes a fourth metal layer, a fifth metal layer and a sixth metal layer, the sixth metal layer is arranged on a side of the second metal layer away from the base substrate, and the fifth metal layer is arranged between the second metal layer and the sixth metal layer; the touch signal line is electrically connected to the second conductive pattern formed on the fourth metal layer through the sixth via hole; the second conductive pattern is electrically connected to the common electrode formed on the fifth metal layer.

Optionally, the data voltage supply line is electrically connected to the driving integrated circuit through a first connection line arranged in the fan-out area; the touch signal line is electrically connected to the driving integrated circuit through a second connection line arranged in the fan-out area; the array substrate further includes a third metal layer, the third metal layer is arranged on a side of the semiconductor layer close to the base substrate; the second connection line is formed in the second metal layer; a part of the first connection line is formed in the first metal layer, and another part of the first connection line is formed in the third metal layer.

In a second aspect, an embodiment of the present disclosure provides a display device comprising the array substrate.

### BRIEF DESCRIPTION OF THE DRAWINGS

FIGS. 1A and 1B are plan layout diagrams of part of an array substrate according to at least one embodiment of the present disclosure;

FIG. 2 is a B-B′ cross-sectional view of the array substrate according to at least one embodiment of the present disclosure shown in FIG. 1A;

FIG. 3 is a B-B′ cross-sectional view of the array substrate according to at least one embodiment of the present disclosure shown in FIG. 1A,

FIG. 4 is a B-B′ cross-sectional view of the array substrate according to at least one embodiment of the present disclosure shown in FIG. 1A;

FIG. 5 is a B-B′ cross-sectional view of the array substrate according to at least one embodiment of the present disclosure shown in FIG. 1A;

FIG. 6 is a layout diagram of the third metal layer in FIG. 1A;

FIG. 7 is a layout diagram of the semiconductor layer in FIG. 1A;

FIG. 8 is a layout diagram of the sixth metal layer in FIG. 1A;

FIG. 9 is a layout diagram of the fifth metal layer in FIG. 1A,

FIG. 10 is a layout diagram of the fourth metal layer in FIG. 1A;

FIG. 11 is a layout diagram of the first metal layer in FIG. 1A;

FIG. 12 is a layout diagram of the second metal layer in FIG. 1A,

FIG. 13 is a superimposed diagram of the third metal layer and the semiconductor layer in FIG. 1A;

FIG. 14 is a B-B′ cross-sectional view of the array substrate according to at least one embodiment of the present disclosure shown in FIG. 1A;

FIG. 15 is a B-B′ cross-sectional view of the array substrate according to at least one embodiment of the present disclosure shown in FIG. 1A;

FIG. 16 is a B-B′ cross-sectional view of the array substrate according to at least one embodiment of the present disclosure shown in FIG. 1A;

FIG. 17 is a cross-sectional view taken along the line C-C′ in FIG. 1B;

FIG. 18 is a cross-sectional view taken along the line C-C′ in FIG. 1B;

FIG. 19 is a cross-sectional view taken along the line C-C′ in FIG. 1B,

FIG. 20 is a superimposed diagram of the third metal layer and the sixth metal layer in FIG. 1A;

FIG. 21 is a layout diagram of an array substrate according to at least one embodiment of the present disclosure;

FIG. 22 is a layout diagram of the third metal layer in FIG. 21;

FIG. 23 is a layout diagram of the semiconductor layer in FIG. 21;

FIG. 24 is a layout diagram of the first metal layer in FIG. 21;

FIGS. 25A and 25B are layout diagrams of the second metal layer in FIG. 21;

FIG. 26 is a layout diagram of the fifth metal layer in FIG. 21;

FIGS. 27A and 27B are layout diagrams of the sixth metal layer in FIG. 21;

FIG. 28 is a layout diagram of the fourth metal layer in FIG. 21;

FIG. 29 is a block diagram of a driving circuit according to at least one embodiment of the present disclosure;

FIG. 30 is a block diagram of a driving circuit according to at least one embodiment of the present disclosure;

FIG. 31 is a circuit diagram of a driving circuit according to at least one embodiment of the present disclosure;

FIG. 32 is a waveform diagram of the potential of the first node PU in the LH pit when at least one embodiment of the driving circuit shown in FIG. 31 is working;

FIG. 33 is a structural diagram of a storage capacitor according to at least one embodiment of the present disclosure.

FIG. 34 is a cross-sectional view taken along line A-A′ in FIG. 33;

FIG. 35 is one embodiment of the two stage of driving circuits shown in FIG. 31;

FIG. 36 is a layout diagram of the third metal layer in FIG. 35;

FIG. 37 is a layout diagram of the semiconductor layer in FIG. 35;

FIG. 38 is a layout diagram of the first metal layer in FIG. 35;

FIG. 39 is a layout diagram of the second metal layer in FIG. 35;

FIG. 40 is a layout diagram of the fourth metal layer in FIG. 35;

FIG. 41 is a layout diagram of a gating control line and a gating portion arranged in a gating transistor arrangement area and included in the array substrate according to at least one embodiment of the present disclosure;

FIG. 42 is a layout diagram of the third metal layer in FIG. 41;

FIG. 43 is a layout diagram of the semiconductor layer in FIG. 41;

FIG. 44 is a layout diagram of the first metal layer in FIG. 41;

FIG. 45 is a layout diagram of the second metal layer in FIG. 41;

FIG. 46 is a layout diagram of the sixth metal layer in FIG. 41;

FIG. 47 is a partial layout diagram of a fan-out area and an integrated circuit arrangement area in an array substrate in at least one embodiment of the present disclosure;

FIG. 48 is a layout diagram of the first metal layer in FIG. 47;

FIG. 49 is a layout diagram of the second metal layer in FIG. 47;

FIG. 50 is a layout diagram of the sixth metal layer in FIG. 47;

FIG. 51 is a layout diagram of the fourth metal layer in FIG. 47;

FIG. 52 is a plan layout diagram of a part of an array substrate according to at least one embodiment of the present disclosure;

FIG. 53 is a layout diagram of the third metal layer in FIG. 52;

FIG. 54 is a layout diagram of the semiconductor layer in FIG. 52;

FIG. 55 is a layout diagram of the first metal layer in FIG. 52;

FIG. 56 is a layout diagram of the second metal layer in FIG. 52;

FIG. 57 is a layout diagram of the fifth metal layer in FIG. 52;

FIG. 58 is a layout diagram of the fourth metal layer in FIG. 52;

FIG. 59 is a superimposed diagram of the third metal layer shown in FIG. 53 and the semiconductor layer shown in FIG. 54;

FIG. 60 is a D-D′ cross-sectional view of the array substrate according to at least one embodiment of the present disclosure shown in FIG. 52;

FIG. 61 is a D-D′ cross-sectional view of the array substrate according to at least one embodiment of the present disclosure shown in FIG. 52;

FIG. 62 is a D-D′ cross-sectional view of the array substrate according to at least one embodiment of the present disclosure shown in FIG. 52;

FIG. 63 is a D-D′ cross-sectional view of the array substrate according to at least one embodiment of the present disclosure shown in FIG. 52;

FIG. 64 is D-D′ cross-sectional view of the array substrate according to at least one embodiment of the present disclosure shown in FIG. 52;

FIG. 65 is D-D′ cross-sectional view of the array substrate according to at least one embodiment of the present disclosure shown in FIG. 52;

FIG. 66 is a D-D′ cross-sectional view of the array substrate according to at least one embodiment of the present disclosure shown in FIG. 52;

FIG. 67 is a cross-sectional view taken along line E-E′ in FIG. 52;

FIG. 68 is a cross-sectional view of four metal layers in the fan-out area;

FIG. 69 is a circuit diagram of a driving circuit according to at least one embodiment of the present disclosure;

FIG. 70 is a layout diagram of the driving circuit shown in FIG. 69;

FIG. 71 is a layout diagram of the third metal layer in FIG. 70;

FIG. 72 is a layout diagram of the semiconductor layer in FIG. 70;

FIG. 73 is a layout diagram of the first metal layer in FIG. 70;

FIG. 74 is a layout diagram of the second metal layer in FIG. 70;

FIG. 75 is a layout diagram of the fourth metal layer in FIG. 70;

FIG. 76 is a schematic diagram showing the positional relationship between touch signal lines and data lines in an array substrate according to at least one embodiment of the present disclosure;

FIG. 77 is a schematic diagram showing the positional relationship between touch signal lines and data lines in an array substrate according to at least one embodiment of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only some of the embodiments of the present disclosure, rather than all of the embodiments. Based on the embodiments in the present disclosure, all other embodiments obtained by those of ordinary skill in the art without making creative efforts fall within the scope of protection of the present disclosure.

As used herein, “about,” “substantially,” or “approximately” includes the stated value and an average value that is within an acceptable range of deviation from the particular value as determined by one of ordinary skill in the art taking into account the measurements and the errors associated with the measurement of the particular quantity (i.e., the limitations of the measurement system).

As used in the present disclosure, “parallel”, “perpendicular”, and “equal” include the situations described and situations similar to the situations described, and the range of the similar situations is within the acceptable deviation range, wherein the acceptable deviation range is determined by a person of ordinary skill in the art taking into account the measurement and the errors associated with the measurement of a particular quantity (i.e., the limitations of the measurement system). For example, “parallel” includes absolute parallelism and approximate parallelism, wherein the acceptable deviation range of approximate parallelism can be, for example, a deviation within 5°; “perpendicular” includes absolute perpendicularity and approximate perpendicularity, wherein the acceptable deviation range of approximate perpendicularity can also be, for example, a deviation within 5°. “Equal” includes absolute equality and approximate equality, wherein the acceptable deviation range of approximate equality can be, for example, the difference between the two equalities is less than or equal to 10% of either one of them.

It will be understood that when a layer or an element is referred to as being on another layer or substrate, it can be directly on the other layer or substrate, or intervening layers may be present between the layer or element and the other layer or substrate.

The present disclosure describes exemplary embodiments with reference to cross-sectional views and/or plan views that are idealized exemplary drawings. In the drawings, the thickness of the layers and the area of the areas are exaggerated for clarity. Therefore, variations in the shapes relative to the drawings due to, for example, manufacturing techniques and/or tolerances are conceivable. Therefore, the exemplary embodiments should not be interpreted as being limited to the shapes of the areas shown herein, but include shape deviations due to, for example, manufacturing. For example, an etched area shown as a rectangle will typically have curved features. Therefore, the areas shown in the drawings are schematic in nature, and their shapes are not intended to illustrate the actual shapes of the areas of the device, and are not intended to limit the scope of the exemplary embodiments.

In the present disclosure, circles, triangles, rectangles, trapezoids, pentagons or hexagons are not in a strict sense, but may be approximate circles, triangles, rectangles, trapezoids, pentagons or hexagons, etc. There may be some small deformations caused by tolerances, and there may be chamfers, arc edges and deformations.

The present disclosure may be thin film transistors or field effect transistors or other devices with the same characteristics. In the embodiments of the present disclosure, in order to distinguish the two electrodes of the transistor except the gate electrode, one of the electrodes is called the first electrode and the other is called the second electrode.

In actual operation, when the transistor is a thin film transistor or a field effect transistor, the first electrode may be a drain electrode, and the second electrode may be a source electrode; or, the first electrode may be a source electrode, and the second electrode may be a drain electrode.

The array substrate described in the embodiment of the present disclosure comprises a plurality of first wiring lines and a plurality of second wiring lines arranged on a base substrate, the first wiring lines and the second wiring lines intersect each other to define a plurality of pixel areas, each of the pixel areas comprises a transistor, a first electrode, a second electrode, a first via hole and a second via hole; an orthographic projection of the first via hole on the base substrate at least partially overlaps an orthographic projection of the first electrode on the base substrate, and an orthographic projection of the second via hole on the base substrate at least partially overlaps the orthographic projection of the first electrode on the base substrate;
The orthographic projection of the first via hole on the base substrate does not overlap the orthographic projection of the second electrode on the base substrate, and the orthographic projection of the second via hole on the base substrate does not overlap the orthographic projection of the second electrode on the base substrate.

In one embodiment of the present disclosure, the first wiring line may be a gate line, the second wiring line may be a data line, the third wiring line may be a touch signal line, the first electrode may be a pixel electrode, and the second electrode may be a common electrode.

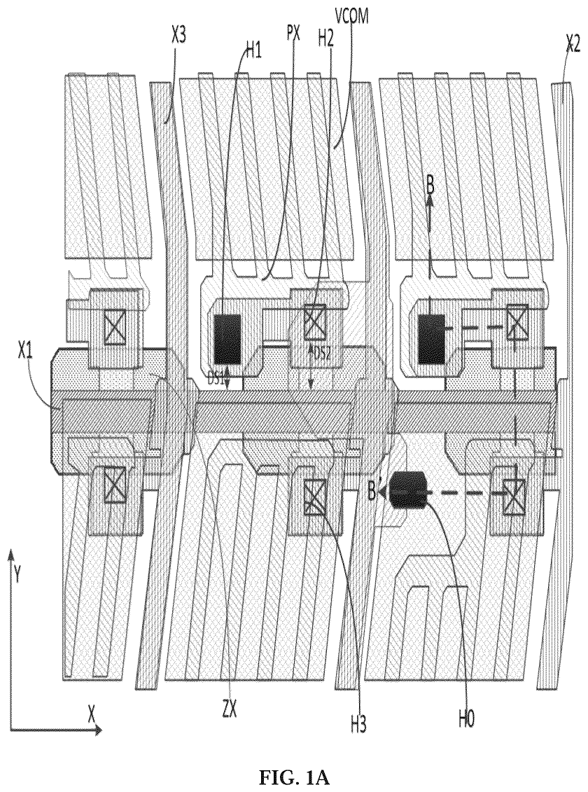

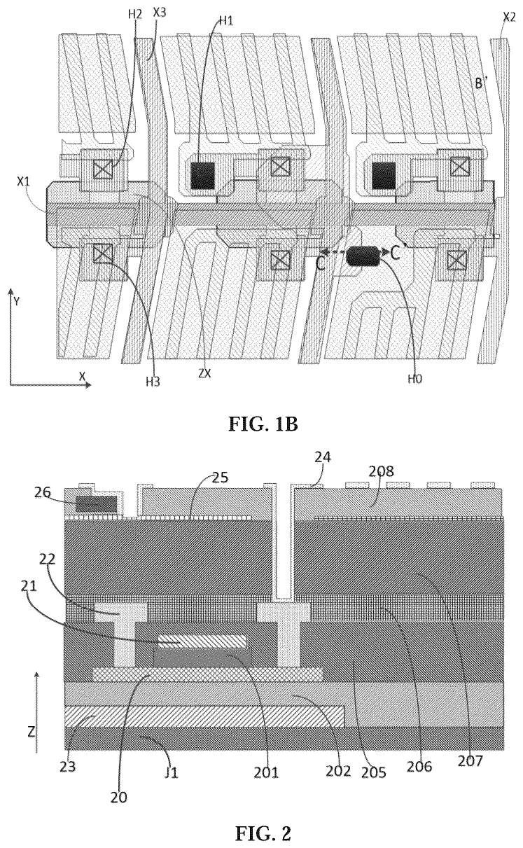

In the embodiment of the present disclosure, the first wiring line X1 and the second wiring line X2 intersect each other to define a plurality of pixel areas, and a transistor, a pixel electrode PX, a common electrode VCOM, a first via hole H1 and a second via hole H2 are arranged in each pixel area;
As shown in FIG. 1A, the first via hole is labeled H1, and the second via hole is labeled H2; a second wiring line is provided below the third wiring line X3;
In FIG. 1A, the pixel electrode is labeled PX, and the common electrode is labeled VCOM;
As shown in FIG. 1A, the orthographic projection of H1 on the base substrate at least partially overlaps the orthographic projection of the pixel electrode PX on the base substrate, and the orthographic projection of H2 on the base substrate at least partially overlaps the orthographic projection of the pixel electrode PX on the base substrate;
The orthographic projection of H1 on the base substrate does not overlap with the orthographic projection of the common electrode VCOM on the base substrate, and the orthographic projection of H2 on the base substrate does not overlap with the orthographic projection of the common electrode VCOM on the base substrate.

As shown in FIG. 1A, the first via hole H1 and the second via hole H2 are located in the same pixel area.

The first via hole H1 is configured to electrically connect the pixel electrode PX and the first conductor portion included in the active pattern, that is, the second via hole H1 is configured to electrically connect the first electrode of the transistor and the first conductor portion of the active pattern;
The first via hole H1 is configured to electrically connect the pixel electrode PX and the first electrode of the transistor;
The second via hole is configured to electrically connect the first electrode of the transistor and the first conductor portion of the active pattern, so that the pixel electrode PX is electrically connected to the first conductor portion of the active pattern.

As shown in FIG. 1A, H1 and H2 are located in the same pixel area, so that the pixel electrode PX is conveniently electrically connected to the first conductor portion of the active pattern.

As shown in FIG. 1A, another pixel area adjacent to the pixel area includes a third via hole H3;
The orthographic projection of the second via hole H2 on the base substrate and the orthographic projection of the third via hole H3 on the base substrate are located on opposite sides of the orthographic projection of the first wiring line X1 on the base substrate.

Optionally, the transistor includes an active pattern;
The orthographic projection of the second via hole on the base substrate at least partially overlaps the orthographic projection of the first conductor portion included in the active pattern on the base substrate; the second via hole is configured to electrically connect the first electrode of the transistor to the first conductor portion of the active pattern;
A part of the first electrode falls into the first via hole, and the first via hole is configured to electrically connect the first electrode and a first conductor portion included in the active pattern.

As shown in FIG. 7, the transistor includes an active pattern A0;
The active pattern AO includes a semiconductor portion B0, a first conductor portion DT1 and a second conductor portion DT2; in FIG. 16, the semiconductor portion is labeled B0, the first conductor portion is labeled DT1, and the second conductor portion is labeled DT2;
As shown in FIG. 16, the orthographic projection of the second via hole H2 on the base substrate at least partially overlaps the orthographic projection of the first conductor portion DT1 on the base substrate; the second via hole H2 is configured to electrically connect the first electrode S1 of the transistor to the first conductor portion DT1;
A part of the pixel electrode PX falls into the first via hole H1, and the first via hole H1 is configured to electrically connect the pixel electrode PX and the first conductor portion DT1.

Optionally, an orthographic projection of the third via on the base substrate at least partially overlaps an orthographic projection of a second conductor portion included in the active pattern on the base substrate; the third via is configured to electrically connect the second electrode of the transistor to the second conductor portion of the active pattern.

As shown in FIG. 1A to FIG. 16, the orthographic projection of the third via hole H3 on the base substrate at least partially overlaps the orthographic projection of the second conductor portion DT2 on the base substrate;
The third via hole H3 is configured to electrically connect the second electrode D2 of the transistor and the second conductor portion DT2.

In one embodiment of the present disclosure, along the first direction, the minimum distance between the orthographic projection of the first via hole on the base substrate and the orthographic projection of the first wiring line on the base substrate is smaller than a minimum distance between the orthographic projection of the second via on the base substrate and the orthographic projection of the first wiring line on the base substrate.

Optionally, the first direction may be a vertical direction.

In the drawings of the present disclosure, the direction labeled X is the second direction, the direction labeled Y is the first direction, and the direction labeled Z is the third direction;
The second direction X may be a horizontal direction, the first direction Y may be a vertical direction, and the third direction Z may be a direction perpendicular to the base substrate.

As shown in FIG. 1A, the spacing between the orthographic projection of the first via hole H1 on the base substrate and the orthographic projection of the first wiring line X1 on the base substrate is labeled DS1, and the spacing between the orthographic projection of the second via hole H2 on the base substrate and the orthographic projection of the first wiring line X1 on the base substrate is labeled DS2;
DS1 is smaller than DS2.

Optionally, the active pattern is in a dumbbell shape; and an angle between an orthographic projection of the active pattern on the base substrate and an orthographic projection of the first wiring line on the base substrate is greater than or equal to 85 degrees and less than or equal to 95 degrees.

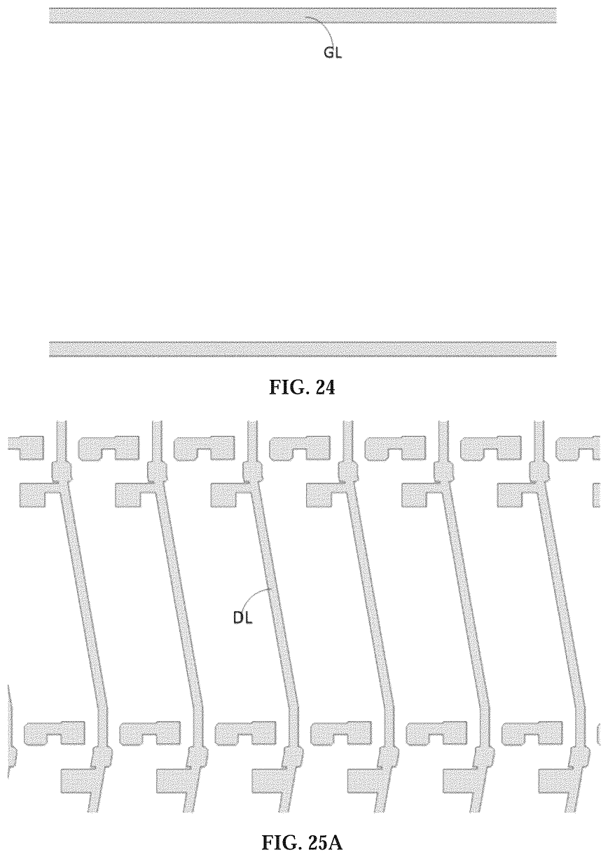

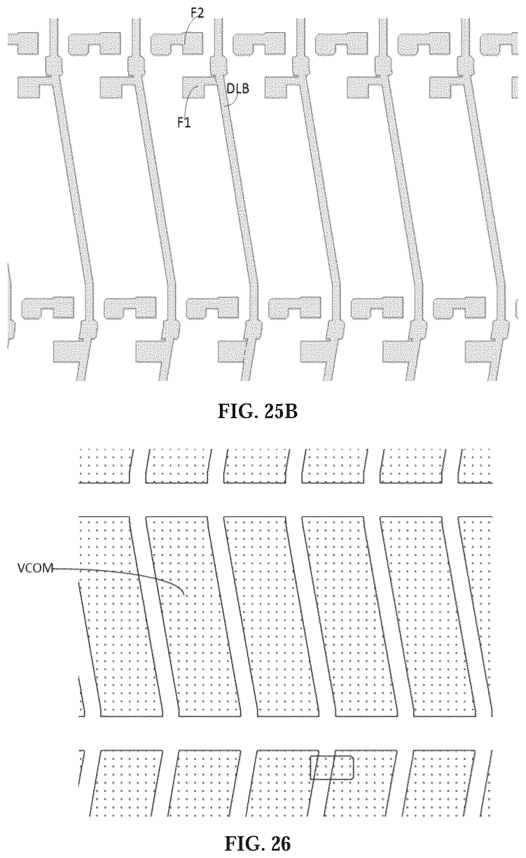

As shown in FIG. 23, the semiconductor layer includes active patterns arranged in an array, and the active pattern A0 is dumbbell-shaped; as shown in FIG. 21, the angle between the orthographic projection of the active pattern A0 on the base substrate and the orthographic projection of the gate line GL on the base substrate is greater than or equal to 85 degrees and less than or equal to 95 degrees; preferably, the angle between the orthographic projection of the active pattern A0 on the base substrate and the orthographic projection of the gate line GL on the base substrate is greater than or equal to 88 degrees and less than or equal to 92 degrees.

In one embodiment of the present disclosure, the second wiring line includes a second wiring line body, a first auxiliary portion, and a second auxiliary portion;
The first auxiliary portion is electrically connected to the second wiring line body, and the second auxiliary portion is in a floating state;
The first auxiliary portion is electrically connected to a second conductor portion included in the active pattern, and the second auxiliary portion is electrically connected to the first electrode.

As shown in FIG. 25B, the first auxiliary portion is labeled F1, and the second auxiliary portion is labeled F2. The first auxiliary portion F1 is electrically connected to the data line body DLB, and the second auxiliary portion is in a floating state;
The first auxiliary portion F1 is electrically connected to the second conductor portion included in the active pattern A0, and the second auxiliary portion F2 is electrically connected to the pixel electrode.

Optionally, the array substrate includes 3a second wiring lines and 2a third wiring lines; a is a positive integer;
The two third wiring lines correspond to the three second wiring lines, and the orthographic projection of the third wiring lines on the base substrate at least partially overlaps the orthographic projection of one of the three second wiring lines on the base substrate.

Optionally, the array substrate includes 3a second wiring lines and a third wiring line; a is a positive integer;
One of the third wiring lines corresponds to three second wiring lines, and an orthographic projection of the third wiring line on the base substrate at least partially overlaps an orthographic projection of one of the three second wiring lines on the base substrate.

In one embodiment of the present disclosure, the array substrate further includes a third wiring line;
The third wiring line includes a signal line body portion and a connection portion electrically connected to each other;
An orthographic projection of the connection portion on the base substrate at least partially overlaps an orthographic projection of the second via hole on the base substrate.

Optionally, the third wiring line may be a touch signal line.

As shown in FIG. 1A and FIG. 8, the third wiring line includes a signal line body portion TX0 and a connection portion L1 electrically connected to each other;
The orthographic projection of the connection portion L1 on the base substrate at least partially overlaps the orthographic projection of the second via hole H2 on the base substrate.

In one embodiment of the present disclosure, the array substrate further includes a light shielding pattern; the light shielding pattern and the third wiring line are arranged in different layers;
The orthographic projection of the connection portion on the base substrate at least partially overlaps the orthographic projection of the light shielding pattern on the base substrate.

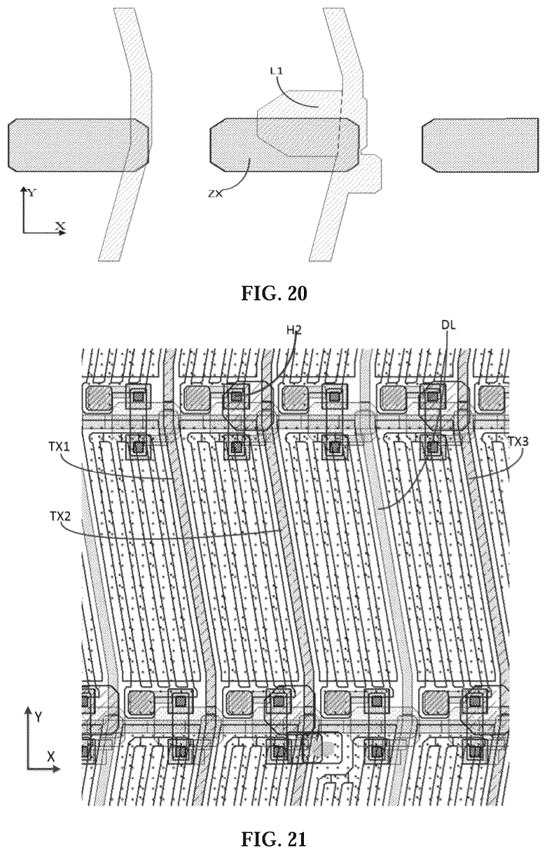

In FIG. 20, L1 is a connection portion, and ZX is a light shielding pattern. The orthographic projection of the connection portion L1 on the base substrate overlaps the orthographic projection of the light shielding pattern ZX on the base substrate, and the overlapping area is greater than or equal to 100 μm² and less than or equal to 150 μm². For example, the overlapping area between the orthographic projection of the connection portion L1 on the base substrate and the orthographic projection of the light shielding pattern ZX on the base substrate may be 122 μm².

In one embodiment of the present disclosure, the array substrate further includes a light shielding pattern;
The orthographic projection of the light shielding pattern on the base substrate covers the orthographic projection of the conductor portion of the active pattern of the transistor on the base substrate to prevent the influence of backlight light emitting on the leakage of the semiconductor portion of the active pattern.

In one embodiment of the present disclosure, the array substrate includes a first metal layer, a second metal layer, a semiconductor layer and a first insulating layer;
The switch transistor comprises an active pattern, a first gate electrode, a first electrode and a second electrode;
The first gate electrode is formed on the first metal layer, the first electrode and the second electrode are formed on the second metal layer, and the active pattern is located in the semiconductor layer;
The first insulating layer is arranged between the first metal layer and the semiconductor layer;
The thickness of the first insulating layer is less than a first thickness threshold; the first thickness threshold is greater than or equal to 800 angstroms and less than or equal to 2000 angstroms;
The first metal layer is arranged on a side of the semiconductor layer away from the base substrate.

In the existing oxide BCE process, since the gate insulating layer is located between the source-drain metal layer and the gate metal layer, and since the source-drain metal layer and the gate metal layer are both metal layers, the thickness of the gate insulating layer cannot be further reduced at the current mass production level, otherwise the risk of ESD between the gate metal layer and the source-drain metal layer will increase. The on-state current of the transistor is inversely proportional to the thickness of the gate insulating layer. The higher the thickness of the gate insulating layer is, the smaller the on-state current of the transistor is. Therefore, the on-state current of the transistor of the BCE structure cannot be further increased due to the limitation of the thickness of the gate insulating layer. Therefore, in order to further increase the on-state current of the transistor, in an embodiment of the present disclosure, by arranged a first metal layer above the semiconductor layer, arranging a second metal layer above the first metal layer (the first metal layer can be a gate metal layer, and the second metal layer can be a source-drain metal layer), a first insulating layer is arranged between the first metal layer and the semiconductor layer, and the embodiment of the present disclosure can reduce the thickness of the first insulating layer to increase the on-state current of the transistor.

In one embodiment of the present disclosure, the transistor may be a top gate structure, and accordingly, the first gate electrode may be a top gate electrode.

In one embodiment of the present disclosure, the thickness of the insulating layer between the first metal layer and the second metal layer can be kept unchanged from that in the related art to prevent ESD.

In one embodiment of the present disclosure, the first insulating layer may be a gate insulating layer, and the thickness of the first insulating layer may be less than a first thickness threshold, which may be greater than or equal to 800 angstroms and less than or equal to 2000 angstroms.

An embodiment of the present disclosure provides a display screen that uses a top-gate process and integrates a touch function.

Optionally, the thickness of the first insulating layer is greater than or equal to 500 angstroms and less than or equal to 2000 angstroms, but is not limited thereto.

In one embodiment of the present disclosure, the active pattern includes a semiconductor portion; the semiconductor portion includes a first semiconductor portion and a second semiconductor portion which are stacked;
The first semiconductor portion is arranged between the second semiconductor portion and the base substrate, and the first semiconductor portion and the second semiconductor portion are made of semiconductor materials with different carrier mobilities.

The active pattern can be made of one or more materials selected from indium gallium zinc oxide (IGZO), indium gallium tin oxide (IGTO), indium tin zinc oxide (ITZO), indium gallium oxide (IGO), indium gallium zinc tin oxide (IGZTO), indium zinc oxide (IZO), zinc tin oxide (ZTO), indium-free metal oxide (In-free OS), and rare earth doped oxide (Ln-OS). The material of the active layer can be amorphous, partially crystalline, single crystal or polycrystalline, and can also be a single layer or multi-layer structure.

Optionally, the first semiconductor portion is made of any one or both of IGZTO and Ln-OS, and the second semiconductor portion is made of any one or both of IGZO and IZO.

In a specific implementation, the semiconductor portion included in the active pattern may include a first semiconductor portion and a second semiconductor portion that are stacked. For example, the first semiconductor portion may be made of IGZTO, and the second semiconductor portion may be made of IGZO, The first semiconductor portion can ensure the mobility of the transistor, and the second semiconductor portion can ensure the stability of the transistor.

In one embodiment of the present disclosure, the array substrate further includes a third metal layer and a second insulating layer;
The third metal layer is arranged between the semiconductor layer and the base substrate, and the second insulating layer is arranged between the semiconductor layer and the third metal layer;
The third metal layer includes a light shielding pattern, and an orthographic projection of the light shielding pattern on the base substrate covers an orthographic projection of a semiconductor portion in the active pattern on the base substrate.

In a specific implementation, the array substrate may further include a third metal layer, which is arranged between the semiconductor layer and the base substrate, and a second insulating layer is arranged between the semiconductor layer and the third metal layer. The orthographic projection of the light shielding pattern included in the third metal layer on the base substrate can cover the orthographic projection of the semiconductor portion in the active pattern on the base substrate to prevent the influence of backlight light emitting on the leakage of the semiconductor portion in the active pattern.

In a specific implementation, the orthographic projection of the light shielding pattern on the base substrate may also cover the orthographic projection of the active pattern on the base substrate.

In one embodiment of the present disclosure, the light shielding pattern is multiplexed as a second gate electrode of the switch transistor.

In a specific implementation, the light shielding pattern can be multiplexed as the second gate electrode of the switch transistor, and the second gate can be a bottom gate. Accordingly, the switch transistor can be a double-gate structure.

Optionally, the active pattern extends along a first direction;
The farthest distance between the edge of the orthographic projection of the light shielding pattern on the base substrate and the edge of the orthographic projection of the active pattern on the base substrate along the second direction is greater than a first distance threshold;
The first distance threshold is greater than or equal to 4 μm; and the first direction intersects with the second direction.

In a specific implementation, the active pattern may extend along a first direction, for example, the first direction may be a vertical direction. At least one embodiment of the present disclosure sets the maximum distance between the edge of the orthographic projection of the light shielding pattern on the base substrate and the edge of the orthographic projection of the active pattern on the base substrate along the second direction to be greater than a first distance threshold to ensure that the orthographic projection of the light shielding pattern on the base substrate can cover the orthographic projection of the active pattern on the base substrate. The first direction intersects with the second direction, for example, the second direction may be a horizontal direction.

For example, the first distance threshold may be greater than or equal to 4 μm. For example, the maximum distance along the second direction between the edge of the orthographic projection of the light shielding pattern on the base substrate and the edge of the orthographic projection of the active pattern on the base substrate may be 6 μm. This distance mainly considers the effect of backlight light emitting on leakage of the active pattern. This distance considers the effect of misalignment caused by the alignment offset of the third metal layer and the semiconductor layer. If the alignment accuracy of the equipment is improved, the distance between the third metal layer and the active pattern may be appropriately reduced to less than 6 μm.

Optionally, the array substrate further includes a fourth metal layer; the first electrode is formed on the fourth metal layer; the fourth metal layer is arranged on a side of the second metal layer away from the base substrate;
The first electrode is electrically connected to the second electrode of the transistor through a first via hole;
The area of the orthographic projection of the first via hole on the base substrate is between 40-80 square micrometers. Optionally, the shape of the orthographic projection of the first via hole on the base substrate is substantially rectangular, which may be greater than or equal to 6 μm×7 μm and less than or equal to 8 μm×10 μm.

In a specific implementation, the array substrate includes a fourth metal layer, a first electrode is formed on the fourth metal layer, the fourth metal layer is electrically connected to the second electrode through a first via hole, and the area of the orthographic projection of the first via hole on the base substrate can be greater than or equal to 6 μm×7 μm and less than or equal to 8 μm×10 μm. For example, the area of the orthographic projection of the first via hole on the base substrate can be 7 μm×8.5 μm. If the area of the first via hole increases, the aperture ratio will be reduced. If the area of the first via hole decreases, there is a risk of not being exposed under the current exposure accuracy. As the exposure accuracy of the device is improved, the size of the first via hole can be further reduced.

In one embodiment of the present disclosure, the array substrate further includes a fifth metal layer; the second electrode is formed on the fifth metal layer; the fifth metal layer is arranged between the fourth metal layer and the second metal layer;
The shortest distance between the orthographic projection of the second electrode on the base substrate and the edge of the orthographic projection of the first via hole on the base substrate is greater than a second distance threshold;
The second distance threshold is greater than 2 μm.

In a specific implementation, the array substrate may further include a fifth metal layer, the second electrode is formed on the fifth metal layer, the fifth metal layer is arranged between the fourth metal layer and the second metal layer, the shortest distance between the orthographic projection of the second electrode on the base substrate and the orthographic projection of the first via on the base substrate is greater than a second distance threshold, the second distance threshold may be greater than 2 μm, for example, the shortest distance between the orthographic projection of the second electrode on the base substrate and the orthographic projection of the first via on the base substrate may be 3 μm, to prevent etching errors and alignment deviations between the second electrode and the first via hole, resulting in the second electrode entering the first via hole, and the first via hole has a conductive pattern included in the fourth metal layer, if the second electrode enters the first via hole, it will short-circuit with the conductive pattern included in the fourth metal layer and display will be poor. If the etching error is reduced and the alignment accuracy is improved, the distance from the first via hole to the second electrode can be further reduced.

Optionally, the first electrode may be a pixel electrode, and the second electrode may be a common electrode.

Optionally, the shortest distance between an orthographic projection of the first electrode on the base substrate and an edge of an orthographic projection of the first via hole on the base substrate is greater than a third distance threshold;
The third distance threshold is greater than or equal to 1.6 μm.

In a specific implementation, the shortest distance between the orthographic projection of the first electrode on the base substrate and the edge of the orthographic projection of the first via hole on the base substrate is greater than a third distance threshold, and the third distance threshold may be greater than or equal to 1.6 μm. For example, the shortest distance between the orthographic projection of the first electrode on the base substrate and the edge of the orthographic projection of the first via hole on the base substrate may be 2.25 μm. Considering the case of alignment offset, the first electrode can still cover the first via hole, thereby ensuring the conductivity between the first electrode and the second electrode. If the alignment accuracy of the device is improved, the distance can be further reduced.

In one embodiment of the present disclosure, the first electrode is electrically connected to the active pattern through a second via hole, and the second electrode is electrically connected to the active pattern through a third via hole;
The shortest distance between the edge of the orthographic projection of the first electrode on the base substrate and the edge of the orthographic projection of the second via hole on the base substrate is greater than a fourth distance threshold;
The shortest distance between the edge of the orthographic projection of the second electrode on the base substrate and the edge of the orthographic projection of the third via hole on the base substrate is greater than a fifth distance threshold;
The fourth distance threshold is greater than or equal to 1.6 μm, and the fifth distance threshold is greater than or equal to 1.6 μm.

In a specific implementation, the first electrode can be electrically connected to the active pattern through the second via hole, and the second electrode can be electrically connected to the active pattern through the third via hole. The shortest distance between the edge of the orthographic projection of the first electrode on the base substrate and the edge of the orthographic projection of the second via hole on the base substrate is set to be greater than the fourth distance threshold; the shortest distance between the edge of the orthographic projection of the second electrode on the base substrate and the edge of the orthographic projection of the third via hole on the base substrate is set to be greater than the fifth distance threshold. The fourth distance threshold and the fifth distance threshold can be greater than or equal to 1.6 μm. For example, the shortest distance between the edge of the orthographic projection of the first electrode on the base substrate and the edge of the orthographic projection of the second via hole on the base substrate can be 2.25 μm, and the shortest distance between the edge of the orthographic projection of the second electrode on the base substrate and the edge of the orthographic projection of the third via hole on the base substrate can be 2.25 μm. Considering the alignment offset, the second metal layer can still cover the second via hole and the third via hole, thereby ensuring the conductivity between the second metal layer and the active pattern. If the alignment accuracy of the equipment is improved, the distance can be further reduced.

FIG. 1A and 1B are plan layout diagrams of parts of an array substrate according to at least one embodiment of the present disclosure.

In FIG. 1A and FIG. 1B, the via hole labeled H1 is the first via hole, the via hole labeled H2 is the second via hole, the via hole labeled H3 is the third via hole, and the via hole labeled H0 is the TX via hole.

In FIG. 1A and FIG. 1B, the light shielding pattern is labeled ZX, the first wiring line is labeled X1, the second wiring line is labeled X2, and the third wiring line is labeled X3.

The first wiring line may be a gate line, the second wiring line may be a data line, and the third wiring line may be a touch signal line.

In the drawings of the present disclosure, the direction labeled X is the second direction, the direction labeled Y is the first direction, and the direction labeled Z is the third direction;
The second direction X may be a horizontal direction, the first direction Y may be a vertical direction, and the third direction Z may be a direction perpendicular to the base substrate.

FIG. 2 is the B-B′ cross-sectional view of the array substrate according to at least one embodiment of the present disclosure shown in FIG. 1.

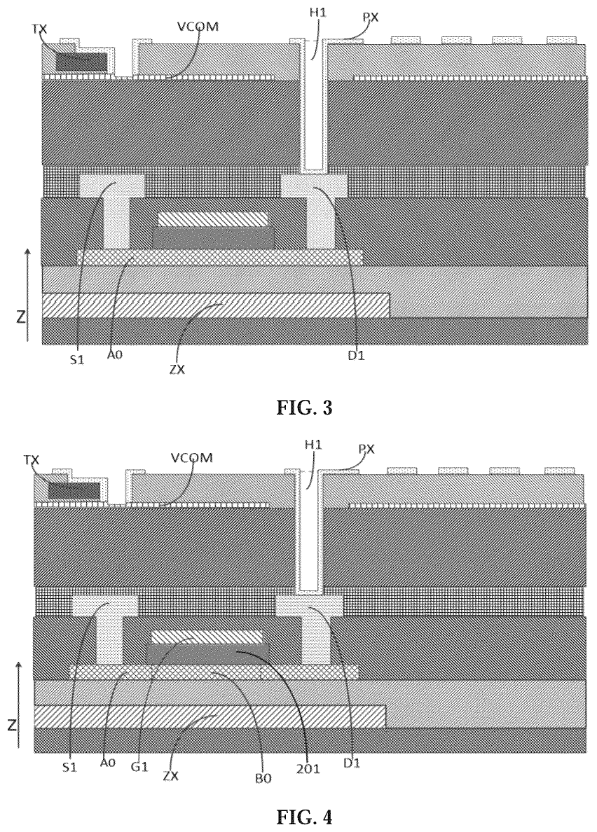

As shown in FIG. 2, the array substrate according to at least one embodiment of the present disclosure includes a first metal layer 21, a second metal layer 22, a semiconductor layer 20, a first insulating layer 201, a third metal layer 23, a second insulating layer 202, a fourth metal layer 24, a fifth metal layer 25, a sixth metal layer 26, a fifth insulating layer 205, a sixth insulating layer 206, a seventh insulating layer 207 and an eighth insulating layer 208;
The third metal layer 23, the semiconductor layer 20, the first metal layer 21, the second metal layer 22, the fifth metal layer 25, the sixth metal layer 26 and the fourth metal layer 24 are arranged in sequence along a direction away from the base substrate J1;
A second insulating layer 202 is arranged between the third metal layer 23 and the semiconductor layer 20;
A first insulating layer 201 is arranged between the semiconductor layer 20 and the first metal layer 21;
A fifth insulating layer 205 is arranged between the first metal layer 21 and the second metal layer 22;
A sixth insulating layer 206 and a seventh insulating layer 207 are stacked between the second metal layer 22 and the fifth metal layer 25; the sixth insulating layer 206 is arranged between the seventh insulating layer 207 and the second metal layer 22;
An eighth insulating layer 208 is arranged between the fourth metal layer 24 and the fifth metal layer 25;
Among them, the first metal layer 21 may be a second gate metal layer, the second metal layer 22 may be a source-drain metal layer, the first insulating layer 201 may be a second gate insulating layer, the third metal layer 23 may be a light shielding metal layer, and the light shielding metal layer may be multiplexed as the first gate electrode metal layer, the fourth metal layer 24 may be a pixel electrode layer, the fifth metal layer 25 may be a common electrode layer, and the sixth metal layer 26 may be a touch layer;
The first insulating layer 201 may be a second gate insulating layer, the second insulating layer 202 may be a first gate insulating layer, the fifth insulating layer 205 may be an interlayer dielectric layer, the sixth insulating layer 206 may be a first passivation layer, the seventh insulating layer 207 may be an organic film layer, and the eighth insulating layer 208 may be a second passivation layer;
As shown in FIG. 3, the switch transistor includes an active pattern A0, a first gate electrode G1, a first electrode S1, and a second electrode D1;
The first gate electrode G1 is formed on the first metal layer 21, the first electrode S1 and the second electrode D1 are formed on the second metal layer 22, and the active pattern A0 is formed on the semiconductor layer 20;
The third metal layer includes a light shielding pattern ZX, and an orthographic projection of the light shielding pattern ZX on the base substrate at least partially overlaps an orthographic projection of the active pattern A0 on the base substrate;
The orthographic projection of the light shielding pattern ZX on the base substrate covers the orthographic projection of the semiconductor portion of the active pattern A0 on the base substrate;
The light shielding pattern ZX can be multiplexed as the second gate electrode of the switch transistor;
The pixel circuit further includes a pixel electrode PX; the pixel electrode PX is formed on the fourth metal layer 24;
The pixel electrode PX is electrically connected to the second electrode D1 through a first via hole H1; the first via hole H1 penetrates the first passivation layer and the organic film layer; that is, the first via hole H1 includes a first sub-via hole penetrating the organic film layer and a second sub-via hole penetrating the first passivation layer;
The display unit further includes a common electrode VCOM, and the common electrode VCOM is formed on the fifth metal layer 25;
In FIG. 3, the line labeled TX is a touch signal line, and the touch signal line is electrically connected to the common electrode VCOM.

As shown in FIG. 4, based on at least one embodiment of the array substrate shown in FIG. 3, the active pattern A0 may include a semiconductor portion B0.

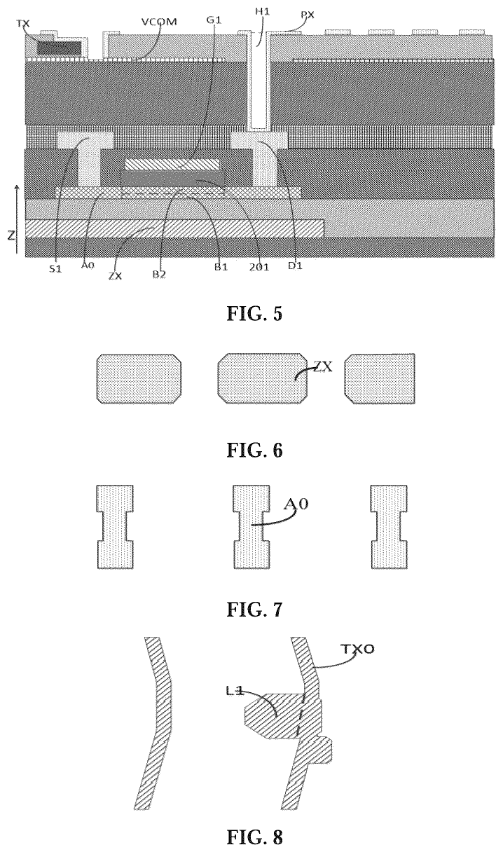

As shown in FIG. 5, based on at least one embodiment of the array substrate shown in FIG. 4, the semiconductor portion includes a first semiconductor portion B1 and a second semiconductor portion B2, and B1 and B2 may be a stacked structure.

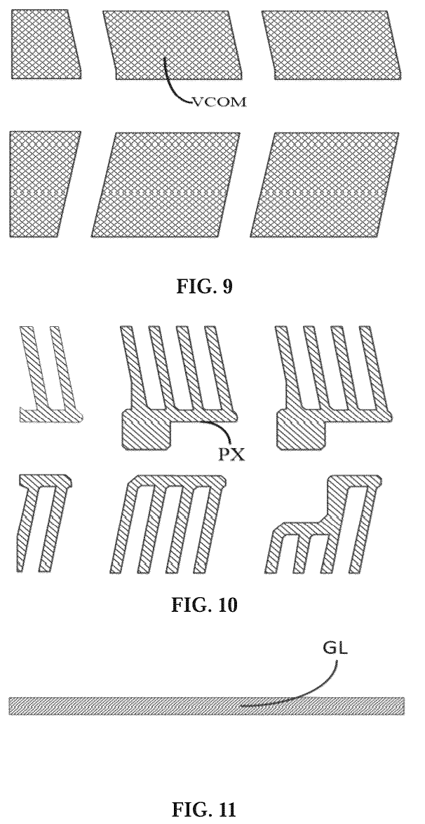

FIG. 6 is a layout diagram of the third metal layer in FIG. 1A, FIG. 7 is a layout diagram of the semiconductor layer in FIG. 1A, FIG. 8 is a layout diagram of the sixth metal layer in FIG. 1A, FIG. 9 is a layout diagram of the fifth metal layer in FIG. 1A, FIG. 10 is a layout diagram of the fourth metal layer in FIG. 1A, FIG. 11 is a layout diagram of the first metal layer in FIG. 1A, and FIG. 12 is a layout diagram of the second metal layer in FIG. 1A.

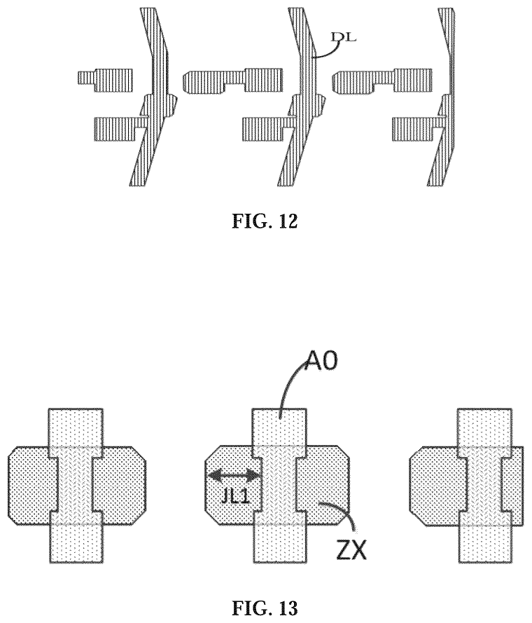

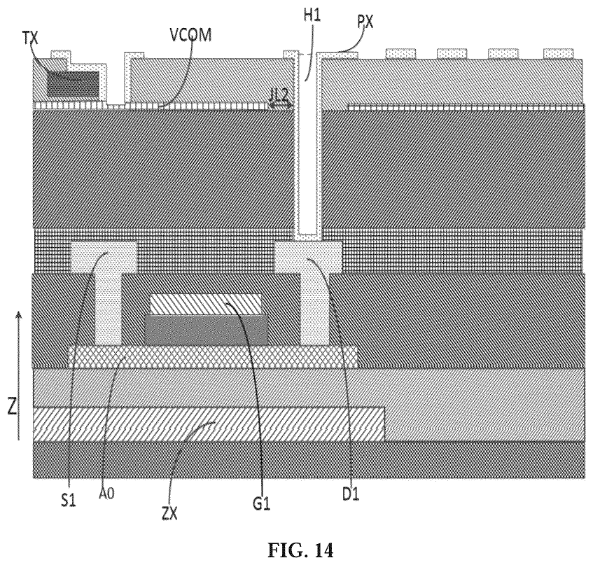

FIG. 13 is a superimposed diagram of the third metal layer and the semiconductor layer in FIG. 1A.

In FIG. 11, the line labeled GL is the gate line, and in FIG. 12, the line labeled DL is the data line.

As shown in FIG. 13, the active pattern A0 extends in the vertical direction, and the longest distance between the edge of the orthographic projection of the light shielding pattern ZX on the base substrate and the edge of the orthographic projection of the active pattern A0 on the base substrate along the second direction is a first distance JL1;
JL1 is greater than the first distance threshold.

In FIG. 1A, the first via hole is labeled H1, and the orthographic projection of the first via hole H1 on the base substrate has an area greater than or equal to 6 μm×7 μm and less than or equal to 8 μm×10 μm.

Optionally, the second direction may be a horizontal direction.

As shown in FIG. 14, based on one embodiment of the array substrate shown in FIG. 3, the shortest distance between the orthographic projection of the common electrode VCOM on the base substrate and the edge of the orthographic projection of the first via hole H1 on the base substrate is a second distance JL2;
The second distance JL2 is greater than the second distance threshold.

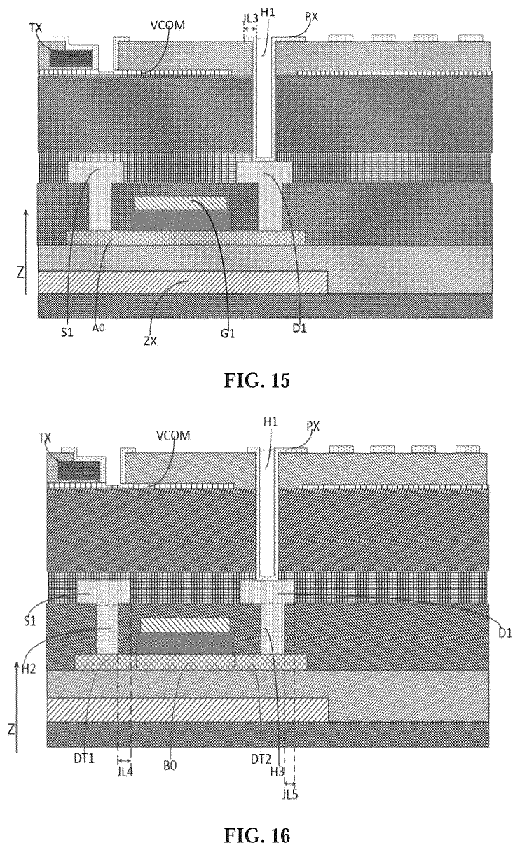

As shown in FIG. 15, based on one embodiment of the array substrate shown in FIG. 3, the shortest distance between the orthographic projection of the pixel electrode PX on the base substrate and the edge of the orthographic projection of the first via hole H1 on the base substrate is a third distance JL3, and the third distance JL3 is greater than the third distance threshold.

As shown in FIG. 16, based on one embodiment of the array substrate shown in FIG. 3, the shortest distance between the edge of the orthographic projection of the first electrode S1 on the base substrate and the edge of the orthographic projection of the second via hole H2 on the base substrate is a fourth distance JL4, and the shortest distance between the edge of the orthographic projection of the second electrode D1 on the base substrate and the edge of the orthographic projection of the second via hole H2 on the base substrate is a fifth distance JL5.

In one embodiment of the present disclosure, the array substrate further includes a fifth metal layer and a sixth metal layer, the fifth metal layer is arranged on a side of the second metal layer away from the base substrate, and the sixth metal layer is arranged on a side of the fifth metal layer away from the base substrate;
The array substrate comprises a third wiring line;
The third wiring line is formed on the sixth metal layer, and the second electrode is formed on the fifth metal layer.

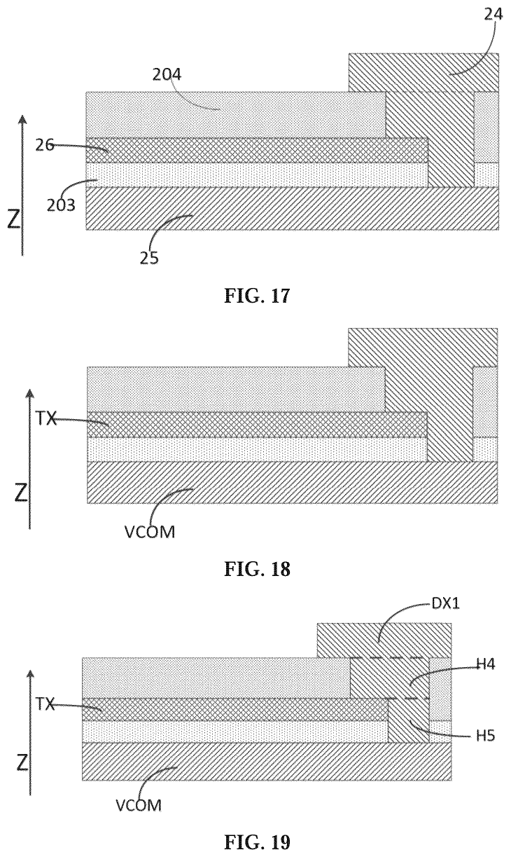

FIG. 17 is the C-C′ cross-portion view in FIG. 1B.

In FIG. 17, only the fourth metal layer 24, the fifth metal layer 25, the sixth metal layer 26, the third insulating layer 203 arranged between the sixth metal layer 26 and the fifth metal layer 25, and the fourth insulating layer 204 arranged between the sixth metal layer 26 and the fourth metal layer 24 are drawn;
The third insulating layer 203 may be a passivation layer, and the fourth insulating layer 204 may be a passivation layer.

In FIG. 18, based on at least one embodiment of the array substrate shown in FIG. 17, the one labeled TX is a touch signal line, and the one labeled VCOM is a common electrode; the touch signal line is electrically connected to the common electrode VCOM.

Optionally, the array substrate further includes a fourth metal layer, a third insulating layer arranged between the sixth metal layer and the fifth metal layer, and a fourth insulating layer arranged between the sixth metal layer and the fourth metal layer; the fourth metal layer is arranged on a side of the sixth metal layer away from the base substrate;
The array substrate comprises a first conductive pattern formed on the fourth metal layer;
The first conductive pattern is electrically connected to the third wiring line through the fourth via hole, and the first conductive pattern is electrically connected to the second electrode through the fourth via hole and the fifth via hole, so that the third wiring line is electrically connected to the second electrode;
The fourth via hole is a via hole penetrating the fourth insulating layer, and the fifth via hole is a via hole penetrating the third insulating layer;
An area of an orthographic projection of the fourth via hole on the base substrate is greater than or equal to 3 μm×6 μm and less than or equal to 5 μm×8 μm.

In a specific implementation, the area of the orthographic projection of the fourth via hole on the base substrate is set to be greater than or equal to 3 μm×6 μm and less than or equal to 5 μm×8 μm. For example, the area of the orthographic projection of the fourth via hole on the base substrate can be 4 μm×7 μm. It is necessary to ensure that the fourth via can still cover the touch signal line and the common electrode after being offset. At the same time, the top of the fourth via hole is covered by the first conductive pattern, and it is necessary to ensure that the first conductive pattern can still cover the fourth via after being offset.

In FIG. 19, based on one embodiment of the array substrate shown in FIG. 18, the via hole labeled H4 is the fourth via hole, the via hole labeled H5 is the fifth via hole, and the area of the orthographic projection of the fourth via hole H4 on the base substrate may be greater than or equal to 3 μm×6 μm and less than or equal to 5 μm×8 μm.

As shown in FIG. 19, the TX via is a half-lapped hole, half of which goes to the touch signal line TX and the other half goes to the common electrode VCOM. The entire TX via is covered with the first conductive pattern DX1. The first conductive pattern DX1 is connected to the touch signal line TX through the hole on the left, and the first conductive pattern DX1 is connected to the common electrode VCOM through the hole on the right, so that the touch signal line TX is electrically connected to the common electrode VCOM.

In one embodiment of the present disclosure, the array substrate includes a sixth metal layer; the array substrate includes a third wiring line, and the third wiring line is formed in the sixth metal layer;
The third wiring line includes a signal line body portion and a connection portion that are interconnected;
The orthographic projection of the connection portion on the base substrate covers the orthographic projection of the spacer on the base substrate, and the connection portion is configured to support the spacer;
The array substrate is included in a display device, and the display device includes a color filter substrate. The spacer is arranged between the color filter substrate and the array substrate.

In a specific implementation, the array substrate may include a touch signal line formed in the sixth metal layer, and the touch signal line may include a signal line body portion and a connection portion that are interconnected, wherein the connection portion can be configured to support a spacer between the color filter substrate and the array substrate.

As shown in FIG. 8, the line labeled TX is a touch signal line. The touch signal line TX may include a signal line body portion TX0 and a connection portion L1 that are interconnected. The connection portion L1 may be configured to support the spacer.

In one embodiment of the present disclosure, the array substrate further includes a third metal layer;
The third metal layer is arranged on a side of the semiconductor layer close to the base substrate; the third metal layer includes a light shielding pattern;
An overlapping area between an orthographic projection of the connection portion on the base substrate and an orthographic projection of the light shielding pattern on the base substrate is greater than or equal to 100 μm² and less than or equal to 150 μm².

FIG. 20 is a superimposed diagram of the third metal layer and the sixth metal layer in FIG. 1A;
In FIG. 20, L1 is a connection portion, and ZX is a light shielding pattern. The orthographic projection of the connection portion L1 on the base substrate overlaps the orthographic projection of the light shielding pattern ZX on the base substrate, and the overlapping area is greater than or equal to 100 μm² and less than or equal to 150 μm². For example, the overlapping area between the orthographic projection of the connection portion L1 on the base substrate and the orthographic projection of the light shielding pattern ZX on the base substrate may be 122 μm².

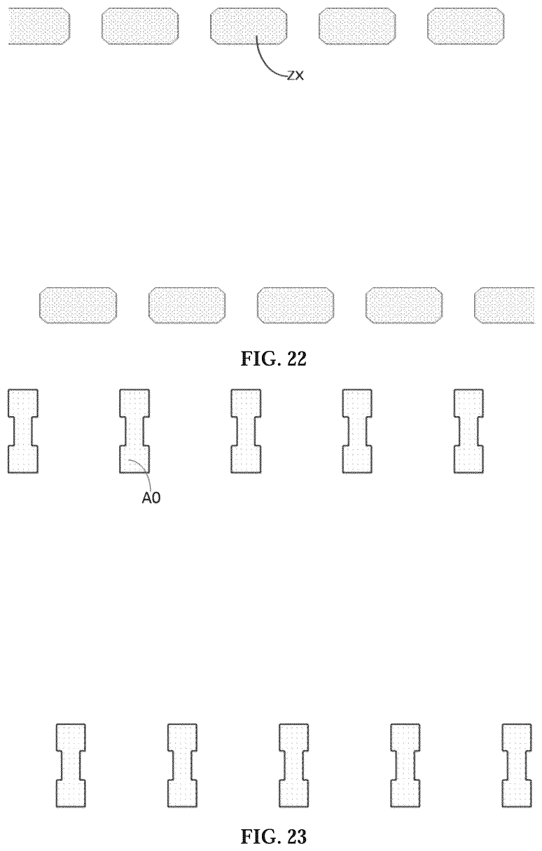

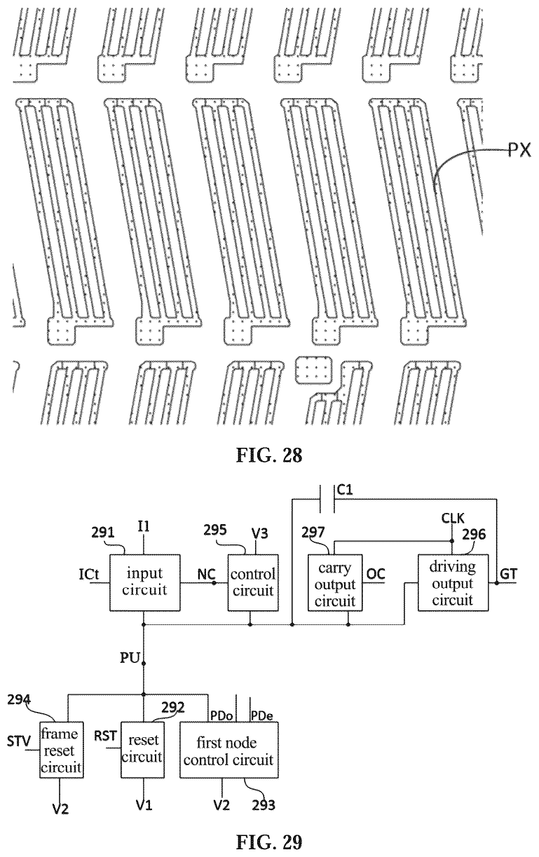

FIG. 21 is a layout diagram of the array substrate described in at least one embodiment of the present disclosure, FIG. 22 is a layout diagram of the third metal layer in FIG. 21, FIG. 23 is a layout diagram of the semiconductor layer in FIG. 21, FIG. 24 is a layout diagram of the first metal layer in FIG. 21, FIGS. 25A and 25B are layout diagrams of the second metal layer in FIG. 21, FIG. 26 is a layout diagram of the fifth metal layer in FIG. 21, FIGS, 27A and 27B are layout diagrams of the sixth metal layer in FIG. 21, and FIG. 28 is a layout diagram of the fourth metal layer in FIG. 21.

In FIG. 21, the line labeled TX1 is a first touch signal line, the line labeled TX2 is a second touch signal line, the line labeled TX3 is a third touch signal line, and the line labeled DL is a data line.

In FIG. 22, the pattern labeled ZX is a light shielding pattern.

As shown in FIG. 22, the light shielding patterns ZX corresponding to the pixel units in the same column but different rows are staggered, that is, the light shielding units corresponding to the pixel units in the same column but different rows are offset by a certain distance. As shown in FIG. 21, the corresponding data lines DL are bent to increase the area of the pixel area as much as possible.

In FIG. 23, the pattern labeled A0 is an active pattern.

As shown in FIG. 23, the semiconductor layer includes active patterns arranged in an array, and the active pattern A0 is dumbbell-shaped; as shown in FIG. 21, the angle between the orthographic projection of the active pattern A0 on the base substrate and the orthographic projection of the gate line GL on the base substrate is greater than or equal to 85 degrees and less than or equal to 95 degrees; preferably, the angle between the orthographic projection of the active pattern A0 on the base substrate and the orthographic projection of the gate line GL on the base substrate is greater than or equal to 88 degrees and less than or equal to 92 degrees.

In FIG. 24, the gate lines are labeled GL.

In FIG. 25A, the data lines are labeled DL.

As shown in FIG. 25B, the first auxiliary portion is labeled F1, and the second auxiliary portion is labeled F2. The first auxiliary portion F1 is electrically connected to the data line body DLB, and the second auxiliary portion is in a floating state;

The first auxiliary portion F1 is electrically connected to the second conductor portion included in the active pattern A0, and the second auxiliary portion F2 is electrically connected to the pixel electrode.

In FIG. 26, the common electrode is labeled VCOM.

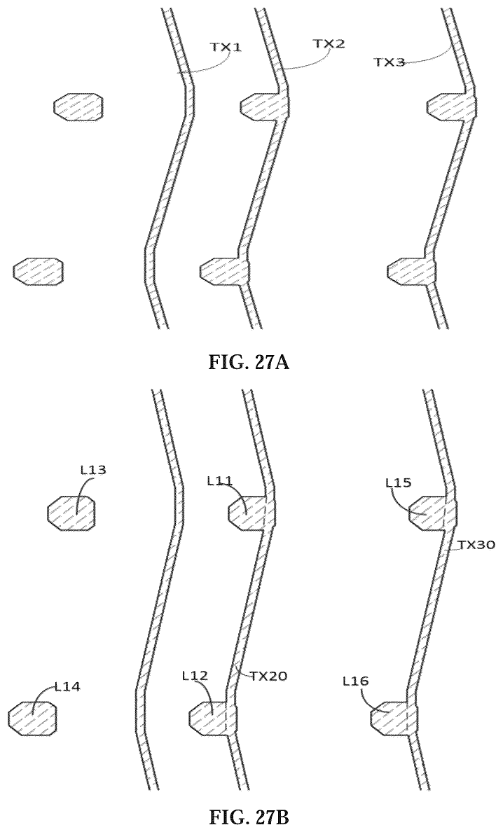

In FIG. 27A, the line labeled TX1 is the first touch signal line, the line labeled TX2 is the second touch signal line, and the line labeled TX3 is the third touch signal line.

In one embodiment of the present disclosure, one touch signal line may be provided in three pixels, or two touch signal lines may be provided in three pixels.

As shown in FIG. 27A, a first touch signal line TX1 and a second touch signal line TX2 are provided in three pixels;
In FIG. 27B, L11 is the first connection portion, L12 is the second connection portion, L13 is the third connection portion, L14 is the fourth connection portion, L15 is the fifth connection portion, and L16 is the sixth connection portion;
L11 and L12 are both electrically connected to a signal line body portion TX20 included in TX2, L13 and L14 are in a floating state, and L15 and L16 are both electrically connected to a signal line body portion TX30 included in TX3.

As shown in FIG. 21, the orthographic projection of each connection portion on the base substrate partially overlaps the orthographic projection of the light shielding pattern on the base substrate and is located to the upper right of the orthographic projection of the light shielding pattern on the base substrate; the orthographic projection of each connection portion on the base substrate overlaps the orthographic projection of the second via hole H2 on the base substrate.

In FIG. 28, the one labeled PX is a pixel electrode.

The array substrate according to at least one embodiment of the present disclosure further includes a driving module arranged on the base substrate; the driving module is arranged in a peripheral area;
The driving module includes a plurality of stages of driving circuits; the driving circuit is configured to provide a driving signal for the pixel circuit.

In a specific implementation, the pixel circuit can be arranged in a display area, and the driving module can be arranged on the first side and/or the second side of the display area; the first side and the second side are opposite sides, for example, the first side can be the left side, and the second side panel can be the right side.

Optionally, the driving circuit includes an input circuit, a reset circuit and a first node control circuit;
The input circuit is electrically connected to an input control terminal, an input terminal and a first node respectively, and is configured to write an input signal provided by the input terminal into the first node under the control of an input control signal provided by the input control terminal;
The reset circuit is electrically connected to a reset line, the first node and a first voltage line respectively, and is configured to control the connection between the first node and the first voltage line under the control of a reset signal provided by the reset line;
The first node control circuit is electrically connected to a first second node, a second second node, a second voltage line and the first node, respectively, and is configured to control the connection between the first node and the second voltage line under the control of a potential of the first second node, and to control the connection between the first node and the second voltage line under the control of a potential of the second second node.

Optionally, the first voltage line may be a first low voltage line, and the second voltage line may be a second low voltage line.

In a specific implementation, the driving circuit may include an input circuit, a reset circuit and a first node control circuit; the input circuit writes an input signal into the first node under the control of an input control signal, the reset circuit resets the potential of the first node under the control of the reset signal, and the first node control circuit controls the potential of the first node under the control of the potential of the second node.

In one embodiment of the present disclosure, the driving circuit further includes a frame reset circuit;
The frame reset circuit is electrically connected to a frame reset line, the first node and the second voltage line respectively, and is configured to control the connection between the first node and the second voltage line under the control of a frame reset signal provided by the frame reset line.

In a specific implementation, the driving circuit may further include a frame reset circuit, and the frame reset circuit resets the potential of the first node under the control of a frame reset signal.

Optionally, the input circuit includes a first transistor and a second transistor;
a gate electrode of the first transistor and a gate electrode of the second transistor are electrically connected to the input control terminal, a first electrode of the first transistor is electrically connected to the input terminal, and a second electrode of the first transistor is electrically connected to the control node;
A first electrode of the second transistor is electrically connected to the control node, and a second electrode of the second transistor is electrically connected to the first node.

In one embodiment of the present disclosure, the driving circuit further includes a control circuit;
The control circuit is electrically connected to the control node, the first node and the third voltage line respectively, and is configured to control the connection between the control node and the third voltage line under the control of the potential of the first node.

In a specific implementation, the driving circuit may further include a control circuit, and the control circuit controls the connection between the control node and the third voltage line under the control of the potential of the first node.

Optionally, the third voltage line may be a high voltage line.

Optionally, the input terminal and the input control terminal are the same signal terminal, and the input terminal is the adjacent previous n stages of carry signal output terminals; or,
The input terminal is the adjacent previous nth stages of the carry signal output terminals, and the input control terminal is the adjacent previous n stages of the driving signal output terminals;
n is a positive integer.

In a specific implementation, the input terminal and the input control terminal can both be the carry signal output terminals of the adjacent previous n stages of driving circuits; or, the input terminal can be the adjacent previous n stages of carry signal output terminals, and the input control terminal can be the adjacent previous n stages of the driving signal output terminals.

Optionally, the reset circuit includes a third transistor and a fourth transistor, and the first node control circuit includes a fifth transistor, a sixth transistor, a seventh transistor and an eighth transistor;
a gate electrode of the third transistor and a gate electrode of the fourth transistor are both electrically connected to the reset line, a first electrode of the third transistor is electrically connected to the first node, a second electrode of the third transistor is electrically connected to a first electrode of the fourth transistor; the second electrode of the third transistor is electrically connected to the control node;
a second electrode of the fourth transistor is electrically connected to the first voltage line;
a gate electrode of the fifth transistor and a gate electrode of the sixth transistor are both electrically connected to the first second node, a first electrode of the fifth transistor is electrically connected to the first node, a second electrode of the fifth transistor is electrically connected to a first electrode of the sixth transistor; a second electrode of the fifth transistor is electrically connected to the control node;
a second electrode of the sixth transistor is electrically connected to the second voltage line;
a gate electrode of the seventh transistor and a gate electrode of the eighth transistor are both electrically connected to the second second node, a first electrode of the seventh transistor is electrically connected to the first node, a second electrode of the seventh transistor is electrically connected to the first electrode of the eighth transistor; a second electrode of the seventh transistor is electrically connected to the control node;
a second electrode of the eighth transistor is electrically connected to the second voltage line.

Optionally, the frame reset circuit includes a ninth transistor and a tenth transistor;
a gate electrode of the ninth transistor is electrically connected to the frame reset line, a first electrode of the ninth transistor is electrically connected to the first node, a second electrode of the ninth transistor is electrically connected to a first electrode of the tenth transistor; a second electrode of the ninth transistor is electrically connected to the control node;
a second electrode of the tenth transistor is electrically connected to the second voltage line.

In one embodiment of the present disclosure, the driving circuit further includes a storage capacitor and a driving signal output terminal; a first electrode plate of the storage capacitor is electrically connected to the first node, and a second electrode plate of the storage capacitor is electrically connected to the driving signal output terminal.

In a specific implementation, the driving circuit may further include a storage capacitor, and the storage capacitor is arranged between the first node and the driving signal output terminal.

In one embodiment of the present disclosure, the driving circuit may include a driving output circuit and a carry output circuit;
The driving output circuit is configured to control the output of a driving signal under the control of the potential of the first node; the carry output circuit is configured to control the output of a carry signal under the control of the potential of the first node.

In one embodiment of the present disclosure, when the array substrate includes a sixth metal layer (the sixth metal layer may be a touch layer), the array substrate adopts a 10 mask process; that is, the array substrate may include a light shielding metal layer, a semiconductor layer, a gate metal layer, an interlayer dielectric layer, a source-drain metal layer, an organic film layer, a common electrode layer, a third insulating layer, a touch layer, a passivation layer and a pixel electrode layer arranged in sequence along a direction away from the base substrate.

As shown in FIG. 29, the driving circuit includes an input circuit 291, a reset circuit 292, a first node control circuit 293, a frame reset circuit 294, a control circuit 295, a storage capacitor C1, a driving output circuit 296, a carry output circuit 297, a driving signal output terminal GT and a carry signal output terminal OC;
The input circuit 291 is electrically connected to the input control terminal ICt, the input terminal I1 and the first node PU respectively, and is configured to write the input signal provided by the input terminal I1 into the first node PU under the control of the input control signal provided by the input control terminal ICt; the input circuit 291 is also electrically connected to the control node NC;
The reset circuit 292 is electrically connected to the reset line RST, the first node PU and the first voltage line V1 respectively, and is configured to control the connection between the first node PU and the first voltage line V1 under the control of the reset signal provided by the reset line RST;
The first node control circuit 293 is electrically connected to the first second node PDo, the second second node PDe, the second voltage line V2 and the first node PU, respectively, and is configured to control the connection between the first node PU and the second voltage line V2 under the control of the potential of the first second node PDo, and to control the connection between the first node PU and the second voltage line V2 under the control of the potential of the second second node PDe.

The frame reset circuit 294 is electrically connected to the frame reset line STV, the first node PU and the second voltage line V2 respectively, and is configured to control the connection between the first node PU and the second voltage line V2 under the control of the frame reset signal provided by the frame reset line STV;
The control circuit 295 is electrically connected to the control node NC, the first node PU and the third voltage line V3 respectively, and is configured to control the connection between the control node NC and the third voltage line V3 under the control of the potential of the first node PU;
The first electrode plate of the storage capacitor C1 is electrically connected to the first node PU, and the second electrode plate of the storage capacitor C1 is electrically connected to the driving signal output terminal GT;
The driving output circuit 296 is electrically connected to the first node PU, the clock signal line CLK and the driving signal output terminal GT respectively, and is configured to control the connection between the driving signal output terminal GT and the clock signal line CLK under the control of the potential of the first node PU, and output the driving signal through the driving signal output terminal GT;
The carry output circuit 297 is electrically connected to the first node PU, the clock signal line CLK and the carry signal output terminal OC respectively, and is configured to control the carry signal output terminal OC to be electrically connected to the clock signal line CLK under the control of the potential of the first node PU, and control the output of the carry signal through the carry signal output terminal OC.

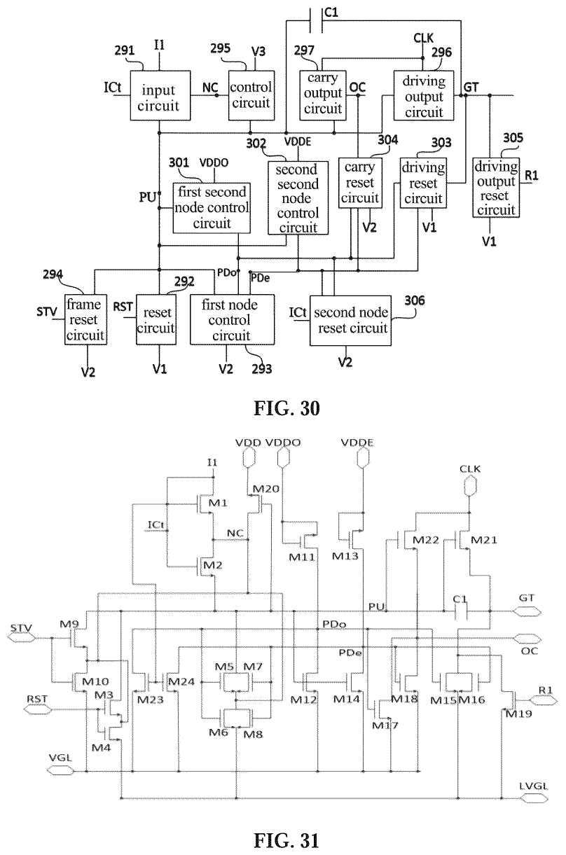

As shown in FIG. 30, based on one embodiment of the driving circuit shown in FIG. 29, the driving circuit may further include a first second node control circuit 301, a second second node control circuit 302, a driving reset circuit 303, a carry reset circuit 304, a driving output reset circuit 305, and a second node reset circuit 306;
The first second node control circuit 301 is electrically connected to the first control voltage line VDDO, the first node PU, the first second node PDo and the second voltage line V2, respectively, and is configured to control the potential of the first second node PDo under the control of the first control voltage provided by the first control voltage line VDDO and the potential of the first node PU;
The second second node control circuit 302 is electrically connected to the second control voltage line VDDE, the first node PU, the first second node PDo and the second voltage line V2, respectively, and is configured to control the potential of the second second node PDe under the control of the second control voltage provided by the second control voltage line VDDE and the potential of the first node PU;
The driving reset circuit 303 is electrically connected to the first second node PDo, the second second node PDe, the driving signal output terminal GT and the first voltage line V1, respectively, and is configured to control the driving signal output terminal GT to be connected to the first voltage line V1 under the control of the potential of the first second node PDo, and to control the driving signal output terminal GT to be connected to the first voltage line V1 under the control of the potential of the second second node PDe;
The carry reset circuit 304 is electrically connected to the first second node PDo, the second second node PDe, the carry signal output terminal OC and the second voltage line V2 respectively, and is configured to control the communication between the carry signal output terminal OC and the second voltage line V2 under the control of the potential of the first second node PDo, and to control the communication between the carry signal output terminal OC and the second voltage line V2 under the control of the potential of the second second node PDe;
The driving output reset circuit 305 is electrically connected to the output reset control line R1, the driving signal output terminal GT and the first voltage line V1 respectively, and is configured to control the connection between the driving signal output terminal GT and the first voltage line V1 under the control of the output reset control signal provided by the output reset control line R1;
The second node reset circuit 306 is electrically connected to the input control terminal ICt, the first second node PDo, the second second node PDe and the second voltage line V2, respectively, and is configured to control the connection between the first second node PDo and the second voltage line V2, and control the connection between the second second node PDe and the second voltage line V2 under the control of the input control signal provided by the input control terminal ICt.

Optionally, the first second node control circuit may include an eleventh transistor and a twelfth transistor;
a gate electrode of the eleventh transistor and a first electrode of the eleventh transistor are both electrically connected to the first control voltage line, and a second electrode of the eleventh transistor is electrically connected to the first second node;
a gate electrode of the twelfth transistor is electrically connected to the first node, a first electrode of the twelfth transistor is electrically connected to the first second node, and a second electrode of the twelfth transistor is electrically connected to the second voltage line;
The second second-node control circuit may include a thirteenth transistor and a fourteenth transistor;
a gate electrode of the thirteenth transistor and a first electrode of the thirteenth transistor are both electrically connected to the second control voltage line, and a second electrode of the thirteenth transistor is electrically connected to the second second node;
a gate electrode of the fourteenth transistor is electrically connected to the first node, a first electrode of the fourteenth transistor is electrically connected to the second second node, and a second electrode of the fourteenth transistor is electrically connected to the second voltage line;
The driving reset circuit may include a fifteenth transistor and a sixteenth transistor;
A gate electrode of the fifteenth transistor is electrically connected to the first second node, a first electrode of the fifteenth transistor is electrically connected to the driving signal output terminal, and a second electrode of the fifteenth transistor is electrically connected to the first voltage line;
A gate electrode of the sixteenth transistor is electrically connected to the second second node, a first electrode of the sixteenth transistor is electrically connected to the driving signal output terminal, and a second electrode of the sixteenth transistor is electrically connected to the first voltage line;
The carry reset circuit may include a seventeenth transistor and an eighteenth transistor;
A gate electrode of the seventeenth transistor is electrically connected to the first second node, a first electrode of the seventeenth transistor is electrically connected to the carry signal output terminal, and a second electrode of the seventeenth transistor is electrically connected to the second voltage line;
A gate electrode of the eighteenth transistor is electrically connected to the second second node, a first electrode of the eighteenth transistor is electrically connected to the carry signal output terminal, and a second electrode of the eighteenth transistor is electrically connected to the second voltage line;
The driving output reset circuit includes a nineteenth transistor;
a gate electrode of the nineteenth transistor is electrically connected to the output reset control line, a first electrode of the nineteenth transistor is electrically connected to the driving signal output terminal, and a second electrode of the nineteenth transistor is electrically connected to the first voltage line;
The control circuit includes a twentieth transistor;
a gate electrode of the twentieth transistor is electrically connected to the first node, a first electrode of the twentieth transistor is electrically connected to the third voltage line, and a second electrode of the twentieth transistor is electrically connected to the control node;
The driving output circuit includes a twenty-first transistor, the carry output circuit includes a twenty-second transistor, and the second node reset circuit 306 includes a twenty-third transistor and a twenty-fourth transistor;
A gate electrode of the twenty-first transistor is electrically connected to the first node, a first electrode of the twenty-first transistor is electrically connected to the clock signal line, and a second electrode of the twenty-first transistor is electrically connected to the driving signal output terminal;
a gate electrode of the twenty-second transistor is electrically connected to the first node, a first electrode of the twenty-second transistor is electrically connected to the clock signal line, and a second electrode of the twenty-second transistor is electrically connected to the carry signal output terminal;
A gate electrode of the twenty-third transistor is electrically connected to the input control terminal ICt, a first electrode of the twenty-third transistor is electrically connected to the first second node, and a second electrode of the twenty-third transistor is electrically connected to the second voltage line;
A gate electrode of the twenty-fourth transistor is electrically connected to the input control terminal ICt, a first electrode of the twenty-fourth transistor is electrically connected to the second second node, and a second electrode of the twenty-fourth transistor is electrically connected to the second voltage line.

As shown in FIG. 31, based on at least one embodiment of the driving circuit shown in FIG. 30,
The input circuit includes a first transistor M1 and a second transistor M2;
The gate electrode of the first transistor M1 and the gate electrode of the second transistor M2 are electrically connected to the input control terminal ICt, the first electrode of the first transistor M1 is electrically connected to the input terminal I1, and the second electrode of the first transistor M1 is electrically connected to the control node NC;
A first electrode of the second transistor M2 is electrically connected to the control node NC, and a second electrode of the second transistor M2 is electrically connected to the first node PU;
The reset circuit includes a third transistor M3 and a fourth transistor M4, and the first node control circuit includes a fifth transistor M5, a sixth transistor M6, a seventh transistor M7 and an eighth transistor M8;
The gate electrode of the third transistor M3 and the gate electrode of the fourth transistor M4 are both electrically connected to the reset line RST, the first electrode of the third transistor M3 is electrically connected to the first node PU, the second electrode of the third transistor M3 is electrically connected to the first electrode of the fourth transistor M4; the second electrode of the third transistor M3 is electrically connected to the control node NC;
A second electrode of the fourth transistor M4 is electrically connected to the first low voltage line LVGL;
The gate electrode of the fifth transistor MS and the gate electrode of the sixth transistor M6 are both electrically connected to the first second node PDo, the first electrode of the fifth transistor M5 is electrically connected to the first node PU, the second electrode of the fifth transistor M5 is electrically connected to the first electrode of the sixth transistor M6; the second electrode of the fifth transistor M5 is electrically connected to the control node NC;
A second electrode of the sixth transistor M6 is electrically connected to the second low voltage line VGL;
The gate electrode of the seventh transistor M7 and the gate electrode of the eighth transistor M8 are both electrically connected to the second second node PDe, the first electrode of the seventh transistor M7 is electrically connected to the first node PU, the second electrode of the seventh transistor M7 is electrically connected to the first electrode of the eighth transistor M8; the second electrode of the seventh transistor M7 is electrically connected to the control node NC;
A second electrode of the eighth transistor M8 is electrically connected to the second low voltage line VGL;
The frame reset circuit includes a ninth transistor M9 and a tenth transistor M10;
The gate electrode of the ninth transistor M9 is electrically connected to the frame reset line STV, the first electrode of the ninth transistor M9 is electrically connected to the first node PU, the second electrode of the ninth transistor M9 is electrically connected to the first electrode of the tenth transistor M10; the second electrode of the ninth transistor M9 is electrically connected to the control node NC;
A second electrode of the tenth transistor M10 is electrically connected to the second low voltage line VGL;
The first second node control circuit may include an eleventh transistor M11 and a twelfth transistor M12;
The gate electrode of the eleventh transistor M11 and the first electrode of the eleventh transistor M11 are both electrically connected to the first control voltage line VDDO, and the second electrode of the eleventh transistor M11 is electrically connected to the first second node PDo;
The gate electrode of the twelfth transistor M12 is electrically connected to the first node PU, the first electrode of the twelfth transistor M12 is electrically connected to the first second node PDo, and the second electrode of the twelfth transistor M12 is electrically connected to the second low voltage line VGL;
The second second node control circuit may include a thirteenth transistor M13 and a fourteenth transistor M14;
The gate electrode of the thirteenth transistor M13 and the first electrode of the thirteenth transistor M13 are both electrically connected to the second control voltage line VDDE, and the second electrode of the thirteenth transistor M13 is electrically connected to the second second node PDe;
The gate electrode of the fourteenth transistor M14 is electrically connected to the first node PU, the first electrode of the fourteenth transistor M14 is electrically connected to the second second node PDe, and the second electrode of the fourteenth transistor M14 is electrically connected to the second low voltage line VGL;
The driving reset circuit may include a fifteenth transistor M15 and a sixteenth transistor M16;
A gate electrode of the fifteenth transistor M15 is electrically connected to the first second node PDo, a first electrode of the fifteenth transistor M15 is electrically connected to the driving signal output terminal GT, and a second electrode of the fifteenth transistor M15 is electrically connected to the first low voltage line LVGL;
A gate electrode of the sixteenth transistor M16 is electrically connected to the second second node PDe, a first electrode of the sixteenth transistor M16 is electrically connected to the driving signal output terminal GT, and a second electrode of the sixteenth transistor M16 is electrically connected to the first low voltage line LVGL;
The carry reset circuit may include a seventeenth transistor M17 and an eighteenth transistor M18;
A gate electrode of the seventeenth transistor M17 is electrically connected to the first second node PDo, a first electrode of the seventeenth transistor M17 is electrically connected to the carry signal output terminal OC, and a second electrode of the seventeenth transistor M17 is electrically connected to the second low voltage line VGL;
A gate electrode of the eighteenth transistor M18 is electrically connected to the second second node PDe, a first electrode of the eighteenth transistor M18 is electrically connected to the carry signal output terminal OC, and a second electrode of the eighteenth transistor M18 is electrically connected to the second low voltage line VGL;
The driving output reset circuit includes a nineteenth transistor M19;
A gate electrode of the nineteenth transistor M19 is electrically connected to the output reset control line R1, a first electrode of the nineteenth transistor M19 is electrically connected to the driving signal output terminal GT, and a second electrode of the nineteenth transistor M19 is electrically connected to the first low voltage line LVGL;
The control circuit includes a twentieth transistor M20;
A gate electrode of the twentieth transistor M20 is electrically connected to the first node PU, a first electrode of the twentieth transistor M20 is electrically connected to the high voltage line VDD, and a second electrode of the twentieth transistor M20 is electrically connected to the control node NC;
The driving output circuit includes a twenty-first transistor M21, the carry output circuit includes a twenty-second transistor M22, and the second node reset circuit 306 includes a twenty-third transistor M23 and a twenty-fourth transistor M24;
The gate electrode of the twenty-first transistor M21 is electrically connected to the first node PU, the first electrode of the twenty-first transistor M21 is electrically connected to the clock signal line CLK, and a second electrode of the twenty-first transistor M21 is electrically connected to the driving signal output terminal GT;
A gate electrode of the twenty-second transistor M22 is electrically connected to the first node PU, a first electrode of the twenty-second transistor M22 is electrically connected to the clock signal line CLK, and a second electrode of the twenty-second transistor M22 is electrically connected to the carry signal output terminal OC;
A gate electrode of the twenty-third transistor M23 is electrically connected to the input control terminal ICt, a first electrode of the twenty-third transistor M23 is electrically connected to the first second node PDo, and a second electrode of the twenty-third transistor M23 is electrically connected to the second low voltage line VGL;
A gate electrode of the twenty-fourth transistor M24 is electrically connected to the input control terminal ICt, a first electrode of the twenty-fourth transistor M24 is electrically connected to the second second node PDe, and a second electrode of the twenty-fourth transistor M24 is electrically connected to the second low voltage line VG.

In at least one embodiment of the driving circuit shown in FIG. 31, the input control terminal ICt is electrically connected to the input terminal I1, and both ICt and I1 can be electrically connected to the carry signal output terminal of the adjacent previous n stages of driving circuits, and n can be a positive integer;
All transistors may be n-type transistors, but are not limited thereto.

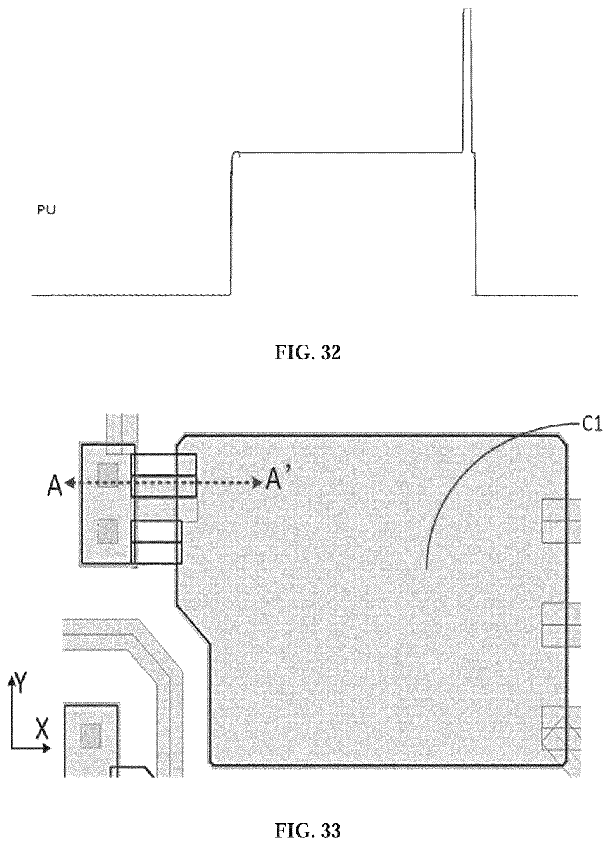

When at least one embodiment of the driving circuit shown in FIG. 31 is working, due to the improvement of the mobility of the top gate process, when the gate-source voltage is 0V, the leakage current of the transistor increases. In order to prevent the increase of the leakage of the transistor electrically connected to the first node PU from affecting the operation of the first node, the transistor electrically connected to the first node PU is connected in series with two transistors, and the input signal is written into the first node PU through M1 and M2. The node between M1 and M2 is the control node NC, and the control node NO is controlled by PU and M20; when the potential of PU is a high voltage, M20 is turned on, and M20 charges the intermediate node of M1 and M2 with a high voltage. The drain-source voltage of M2 is reduced compared to when only one input transistor is used, which improves the leakage of the first node and improves the stability of the driving circuit. FIG. 32 is the potential of the first node PU in the LH pit when at least one embodiment of the driving circuit shown in FIG. 31 is working. It can be seen that in the LH pit, the potential of the first node PU can be well maintained at a high voltage, and the driving circuit has good stability;
In one embodiment of the driving circuit shown in FIG. 31, the intermediate node between M5 and M6, the intermediate node between M7 and M8, the intermediate node between M11 and M12, and the intermediate node between M13 and M14 are all electrically connected to the control node NC to reduce the leakage current of the first node PU.

In one embodiment of the present disclosure, the array substrate further includes a third metal layer and a second insulating layer; the third metal layer is arranged on a side of the semiconductor layer close to the base substrate, and the second insulating layer is arranged between the semiconductor layer and the third metal layer;
The first electrode plate is formed on the first metal layer, and the second electrode plate includes a first electrode plate portion and a second electrode plate portion electrically connected to each other;
The first electrode plate portion is formed on the second metal layer, and the second electrode plate portion is formed on the third metal layer;
An orthographic projection of the first electrode plate on the base substrate, an orthographic projection of the first electrode plate portion on the base substrate, and an orthographic projection of the second electrode plate portion on the base substrate at least partially overlap.

In a specific implementation, the array substrate may further include a third metal layer and a second insulating layer, the first electrode plate may be formed on the first metal layer, the second electrode plate may include a first electrode plate portion and a second electrode plate portion, the first electrode plate portion is formed on the second metal layer, the second electrode plate portion is formed on the third metal layer, and the orthographic projection of the first electrode plate on the base substrate, the orthographic projection of the first electrode plate portion on the base substrate, and the orthographic projection of the second electrode plate portion on the base substrate at least partially overlap.

In a specific implementation, a first metal layer, a second metal layer and a third metal layer can be configured to form a storage capacitor. The first metal layer and the second metal layer on the upper layer form a capacitor. At the same time, the first metal layer and the third metal layer on the lower layer form a capacitor, and the size of the capacitor is proportional to the area of the electrode plate. Therefore, for a storage capacitor of the same size, the area of the electrode plate can be reduced by half when three layers of metal are used compared to when two layers of metal are used, which can reduce the space occupied by the driving circuit and facilitate the realization of a narrow frame. In at least one embodiment of the present disclosure, the electrode plate of the storage capacitor is located in a blank area of the driving circuit architecture (where there is no wiring line or transistor), and the capacitance value of the storage capacitor is greater than or equal to 1 pF and less than or equal to 3 pF.

FIG. 33 is a structural diagram of a storage capacitor.

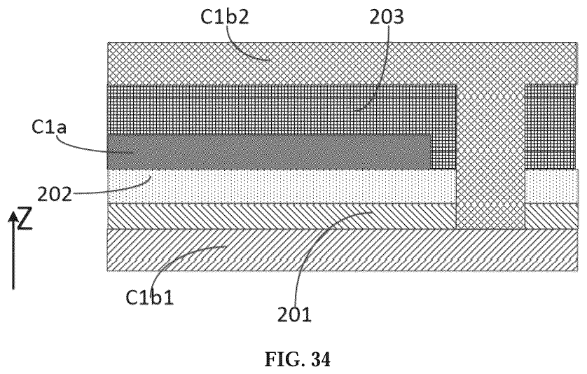

FIG. 34 is a cross-sectional view taken along line A-A′ in FIG. 33.

In FIG. 34, C1a is an electrode plate, C1b1 is a first electrode plate portion, and C1b2 is a second electrode plate portion; C1b1 and C1b2 are electrically connected.

In FIGS. 34, 201 is a first insulating layer, 202 is a second insulating layer, and 203 is a third insulating layer.

Optionally, the first metal layer may be a gate metal layer, the second metal layer may be a source-drain metal layer, and the third metal layer may be a light shielding metal layer.

Optionally, the first electrode plate includes a first first electrode plate portion, a second first electrode plate portion and a third first electrode plate portion electrically connected to each other;
The first electrode portion includes a first second electrode portion, a second second electrode portion and a third second electrode portion electrically connected to each other;
The second electrode portion includes a first third electrode portion, a second third electrode portion and a third third electrode portion electrically connected to each other;
The first first electrode plate portion, the second first electrode plate portion and the third first electrode plate portion are all formed in the first metal layer, the first second electrode plate portion, the second second electrode plate portion and the third second electrode plate portion are all formed in the second metal layer, and the first third electrode plate portion, the second third electrode plate portion and the third third electrode plate portion are all formed in the third metal layer.

In a specific implementation, the first electrode plate may include three first electrode plate portions, the first electrode plate portion may include three second electrode plate portions, and the second electrode plate portion may include three third electrode plate portions. The electrode plate portions may be set by utilizing the space between the transistor and the signal line, as well as the space between the transistors. This may increase the capacitance value of the storage capacitor while effectively utilizing the space.

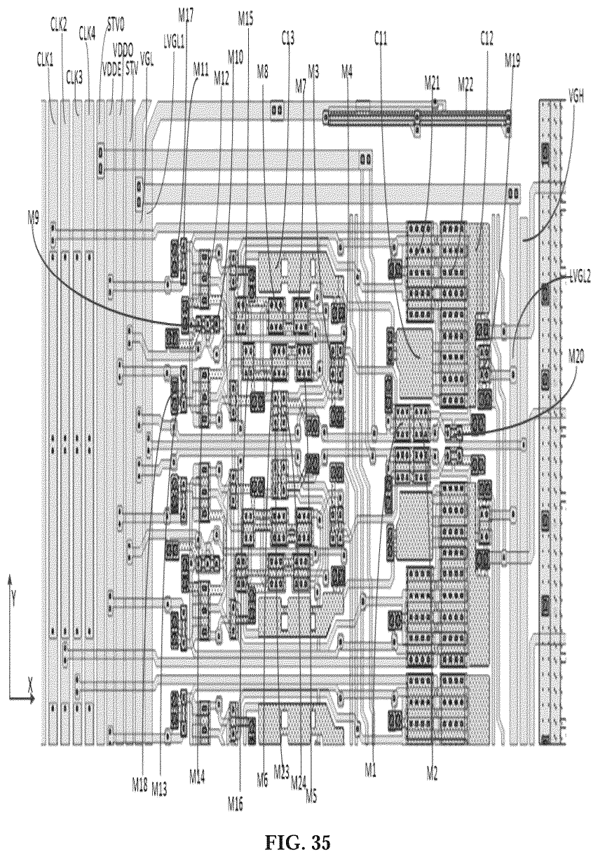

FIG. 35 is the layout diagram of the two stages of driving circuits shown in FIG. 31.

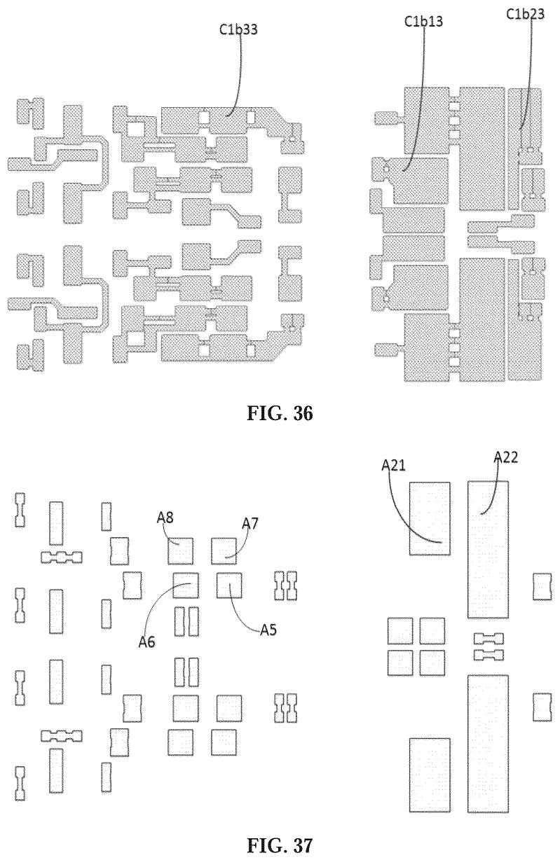

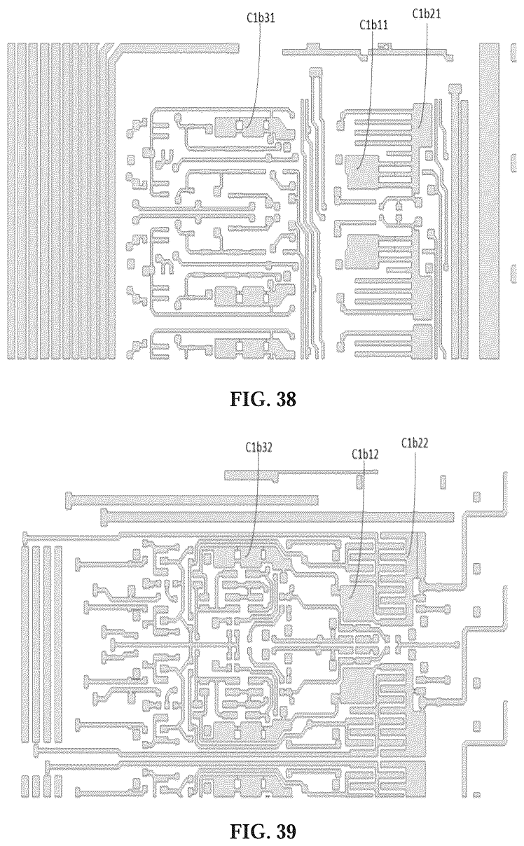

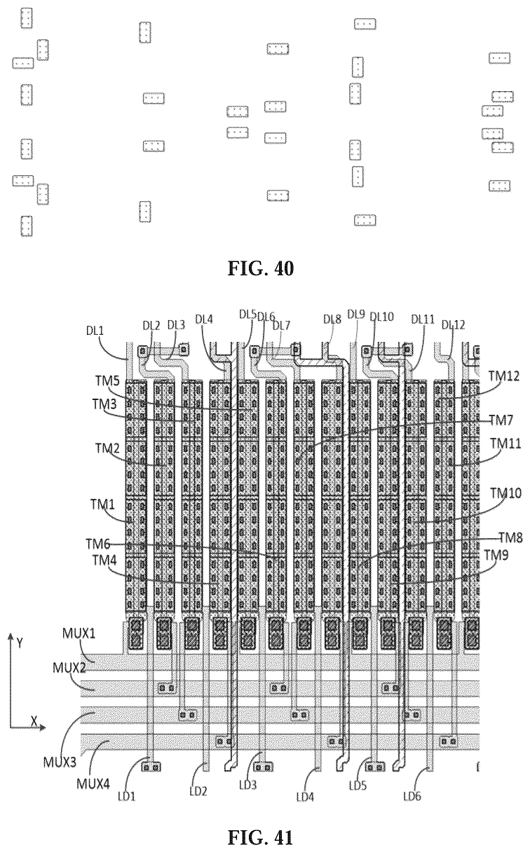

FIG. 36 is a layout diagram of the third metal layer in FIG. 35, FIG. 37 is a layout diagram of the semiconductor layer in FIG. 35, FIG. 38 is a layout diagram of the first metal layer in FIG. 35, FIG. 39 is a layout diagram of the second metal layer in FIG. 35, and FIG. 40 is a layout diagram of the fourth metal layer in FIG. 35.

Among them, the third metal layer may be a light shielding metal layer, the first metal layer may be a gate metal layer, the second metal layer may be a source-drain metal layer, and the fourth metal layer may be a pixel electrode layer.

In FIG. 35, the first low voltage line is labeled LVGL1, the second first low voltage line is labeled LVGL2, the first part of the storage capacitor C1 is labeled C11, the second part of the storage capacitor C1 is labeled C12, and the third part of the storage capacitor C1 is labeled C13; the high voltage line is labeled VGH, the first clock signal line is labeled CLK1, the second clock signal line is labeled CLK2, the third clock signal line is labeled CLK3, the fourth clock signal line is labeled CLK4, and the start signal line is labeled STV0.

In FIG. 36, the first third electrode plate portion is labeled C1b13, the second third electrode plate portion is labeled C1b23, and the third third electrode plate portion is labeled C1b33.

In FIG. 37, A21 is an active pattern of M21, A22 is an active pattern of M22, A5 is an active pattern of M5, A6 is an active pattern of M6, A7 is an active pattern of M7, and A8 is an active pattern of M8.

In FIG. 38, the first first electrode plate portion is labeled C1b11, the second first electrode plate portion is labeled C1b21, and the third first electrode plate portion is labeled C1b31.

In FIG. 39, the first second electrode plate portion is labeled C1b12, the second second electrode plate portion is labeled C1b22, and the third second electrode plate portion is labeled C1b32.

In FIG. 40, each pattern is a conductive pattern.

As shown in FIGS. 35 to 40, the orthographic projection of C1b11 on the base substrate, the orthographic projection of C1b12 on the base substrate, and the orthographic projection of C1b13 on the base substrate at least partially overlap;
The orthographic projection of C1b21 on the base, the orthographic projection of C1b22 on the base, and the orthographic projection of C1b23 on the base at least partially overlap;
The orthographic projection of C1b31 on the base substrate, the orthographic projection of C1b32 on the base substrate, and the orthographic projection of C1b33 on the base substrate at least partially overlap.

In one embodiment of the present disclosure, the driving circuit includes a driving output circuit and a carry output circuit;
The driving output circuit is configured to control the output of the driving signal under the control of the potential of the first node; the carry output circuit is configured to control the output of the carry signal under the control of the potential of the first node;
An orthographic projection of an active pattern of a transistor included in the driving output circuit on the base substrate and an orthographic projection of the first first electrode portion on the base substrate are arranged along a first direction;
An active pattern of a transistor included in the carry output circuit is arranged on a side of the active pattern of the transistor included in the driving output circuit close to the display area;
An orthographic projection of the second first electrode portion on the base substrate is arranged on a side of the orthographic projection of the active pattern of the transistor included in the carry output circuit on the base substrate close to the display area;
An orthographic projection of the third first electrode portion on the base substrate and the active pattern of the transistor included in the first node control circuit are arranged along the first direction.

Optionally, the first direction may be a vertical direction.

As shown in FIGS. 35 to 40, the driving output circuit includes a twenty-first transistor M21, and the carry output circuit includes a twenty-second transistor M22;
The orthographic projection of the active pattern A21 of the twenty-first transistor M21 on the base substrate and the orthographic projection of the first first electrode plate portion C1b11 on the base substrate are arranged in the vertical direction;
The active pattern A22 of the twenty-second transistor M22 is arranged on a side of the active pattern A21 of the twenty-first transistor M21 close to the display area;
The orthographic projection of the first second electrode portion C1b12 on the base substrate is arranged on a side of the orthographic projection of the active pattern A22 of the twenty-second transistor M22 on the base substrate close to the display area;
The first node control circuit includes a fifth transistor M5, a sixth transistor M6, a seventh transistor M7 and an eighth transistor M8;
The orthographic projection of the first third electrode portion C1b13 on the base substrate and the active pattern A5 of M5 are arranged along the vertical direction;
The orthographic projection of the first third electrode portion C1b13 on the base substrate and the active pattern A6 of M6 are arranged in the vertical direction;
The orthographic projection of the first third electrode portion C1b13 on the base substrate and the active pattern A7 of M7 are arranged in the vertical direction;
The orthographic projection of the first third electrode portion C1b13 on the base substrate and the active pattern A8 of M8 are arranged along the vertical direction.

In one embodiment of the present disclosure, the peripheral area includes a fan-out area and a gating transistor arrangement area arranged between the fan-out area and the display area;
The array substrate comprises M gating control lines and a gating portion arranged in the gating transistor arrangement area; the gating portion comprises a plurality of gating portions; M is an integer greater than 1;
The gating portion includes a plurality of gating transistors; the gate electrodes of the plurality of gating transistors are electrically connected to the corresponding gating control lines, the first electrodes of the plurality of gating transistors are electrically connected to the corresponding data voltage supply lines, and the second electrodes of the plurality of gating transistors are electrically connected to the corresponding data lines.

In a specific implementation, the peripheral area may include a gating transistor setting area arranged between the display area and the fan-out area, in which M gating control lines and a gating portion are arranged, and the gating portion includes multiple gating portions, and the gating portion includes a plurality of gating transistors. The plurality of gating transistors control the connection or disconnection between the data voltage supply line and the data line under the control of the gating control signal provided by the corresponding gating control line.

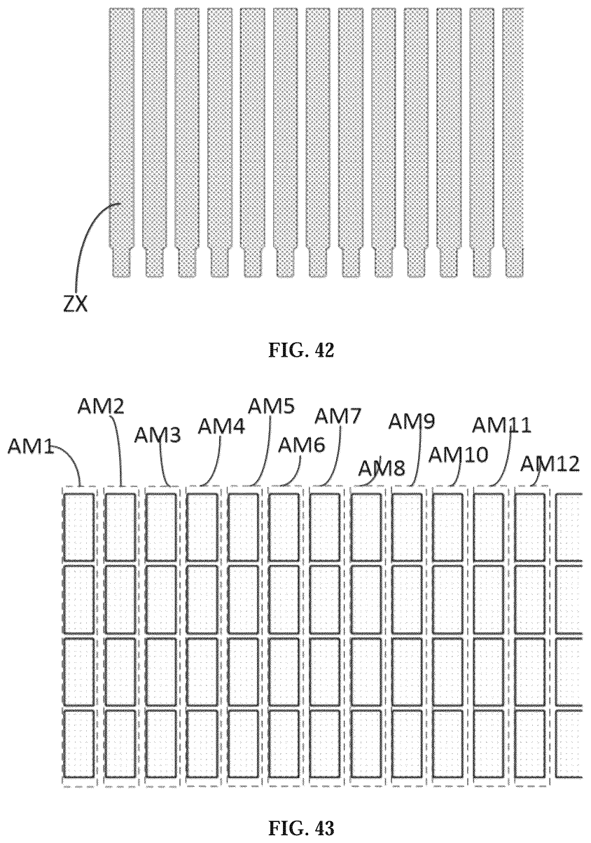

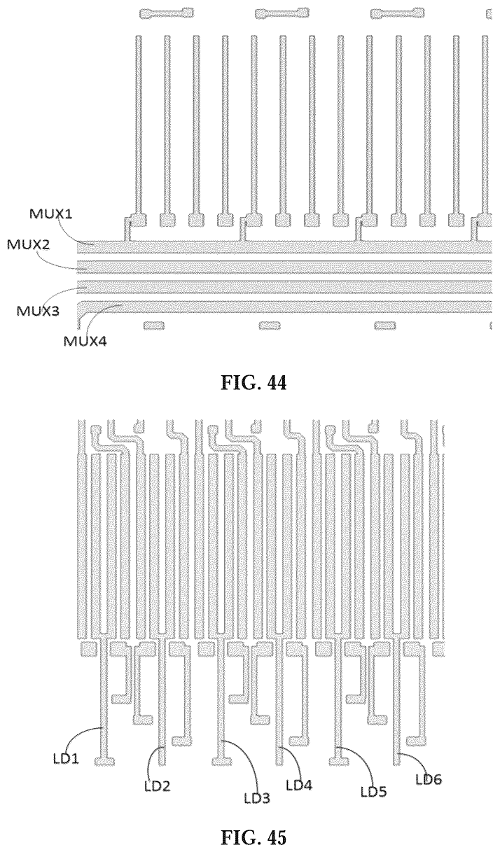

FIG. 41 is a layout diagram of a gating control line and a gating portion arranged in a gating transistor arraignment area, included in the array substrate according to at least one embodiment of the present disclosure.

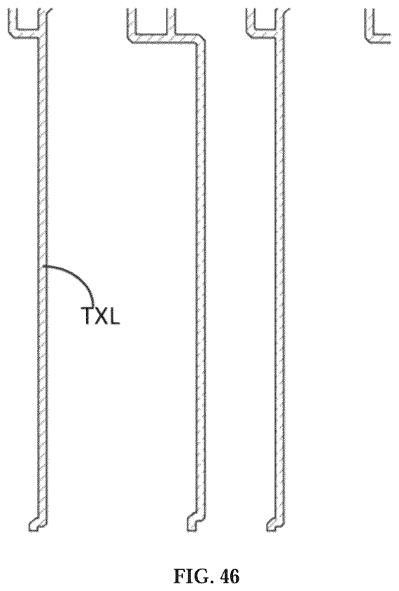

FIG. 42 is a layout diagram of the third metal layer in FIG. 41, FIG. 43 is a layout diagram of the semiconductor layer in FIG. 41, FIG. 44 is a layout diagram of the first metal layer in FIG. 41, FIG. 45 is a layout diagram of the second metal layer in FIG. 41, and FIG. 46 is a layout diagram of the sixth metal layer in FIG. 41.

In FIG. 41, MUX1 is the first gating control line, MUX2 is the second gating control line, MUX3 is the third gating control line, and MUX4 is the fourth gating control line;
The first gating transistor is labeled TM1, the second gating transistor is labeled TM2, the third gating transistor is labeled TM3, the fourth gating transistor is labeled TM4, the fifth gating transistor is labeled TM5, the sixth gating transistor is labeled TM6, the seventh gating transistor is labeled TM7, the eighth gating transistor is labeled TM8, the ninth gating transistor is labeled TM9, the tenth gating transistor is labeled TM10, the eleventh gating transistor is labeled TM11, and the twelfth gating transistor is labeled TM12;
The line labeled LD1 is a first data voltage supply line, the line labeled LD2 is a second data voltage supply line, the line labeled LD3 is a third data voltage supply line, the line labeled LD4 is a fourth data voltage supply line, the line labeled LD5 is a fifth data voltage supply line, and the line labeled LD6 is a sixth data voltage supply line;
DL1 is the first data line, DL2 is the second data line, DL3 is the third data line, DL4 is the fourth data line, DL5 is the fifth data line, DL6 is the sixth data line, DL7 is the seventh data line, DL8 is the eighth data line, DL9 is the ninth data line, DL10 is the tenth data line, DL11 is the eleventh data line, and DL12 is the twelfth data line;
The gate electrode of TM1 is electrically connected to the first gating control line MUX1, the first electrode of TM1 is electrically connected to the first data voltage supply line LD1, and the second electrode of TM1 is electrically connected to the first data line DL1;
The gate line of TM2 is electrically connected to the second gating control line MUX2, the first electrode of TM2 is electrically connected to the first data voltage supply line LD1, and the second electrode of TM2 is electrically connected to the second data line DL2;
The gate electrode of TM3 is electrically connected to the third gating control line MUX3, the first electrode of TM3 is electrically connected to the second data voltage supply line LD2, and the second electrode of TM3 is electrically connected to the third data line DL3;
The gate line of TM4 is electrically connected to the fourth gating control line MUX4, the first electrode of TM4 is electrically connected to the second data voltage supply line LD2, and the second electrode of TM4 is electrically connected to the fourth data line DL4;
the gate electrode of TM5 is electrically connected to the first gating control line MUX1, a first electrode of TM5 is electrically connected to the third data voltage supply line LD3, and a second electrode of TMS is electrically connected to the fifth data line DL5;
The gate line of TM6 is electrically connected to the second gating control line MUX2, the first electrode of TM6 is electrically connected to the third data voltage supply line LD3, and the second electrode of TM6 is electrically connected to the sixth data line DL6;
A gate electrode of TM7 is electrically connected to the third gating control line MUX3, a first electrode of TM7 is electrically connected to the fourth data voltage supply line LD4, and a second electrode of TM7 is electrically connected to the seventh data line DL7;
The gate electrode of TM8 is electrically connected to the fourth gating control line MUX4, the first electrode of TM8 is electrically connected to the fourth data voltage supply line LD4, and the second electrode of TM8 is electrically connected to the eighth data line DL8;
A gate electrode of TM9 is electrically connected to the first gating control line MUX1, a first electrode of TM9 is electrically connected to the fifth data voltage supply line LD5, and a second electrode of TM9 is electrically connected to the ninth data line DL9;
The gate electrode of TM10 is electrically connected to the second gating control line MUX2, the first electrode of TM10 is electrically connected to the fifth data voltage supply line LD5, and the second electrode of TM10 is electrically connected to the tenth data line DL10;
The gate electrode of TM11 is electrically connected to the third gating control line MUX3, the first electrode of TM11 is electrically connected to the sixth data voltage supply line LD6, and the second electrode of TM11 is electrically connected to the eleventh data line DL11;
A gate electrode of TM12 is electrically connected to the fourth gating control line MUX4, a first electrode of TM12 is electrically connected to the sixth data voltage supply line LD6, and a second electrode of TM12 is electrically connected to the twelfth data line DL12.
In FIG. 41, the gating portion includes TM1-TM12, and the gating portion includes a first gating portion, a second gating portion, a third gating portion, a fourth gating portion, a fifth gating portion, and a sixth gating portion;
The first gating portion includes TM1 and TM2; the second gating portion includes TM3 and TM4; the third gating portion includes TM5 and TM6; the fourth gating portion includes TM7 and TM8; the fifth gating portion includes TM9 and TM10; and the sixth gating portion includes TM11 and TM12.

In FIG. 43, AM1 is the active pattern of TM1, AM2 is the active pattern of TM2, AM3 is the active pattern of TM3, AM4 is the active pattern of TM4, AM5 is the active pattern of TM5, AM6 is the active pattern of TM6, AM7 is the active pattern of TM7, AM8 is the active pattern of TM8, AM9 is the active pattern of TM9, AM10 is the active pattern of TM10, AMI1 is the active pattern of TM11, and AM12 is the active pattern of TM12.

In FIG. 46, the one labeled TXL is a touch signal line.

Optionally, in the gating transistor arrangement area; the array substrate further includes a third metal layer; the third metal layer is arranged on a side of the semiconductor layer close to the base substrate;
In the gating transistor arrangement area, the conductive pattern on the third metal layer is in a floating state.

In a specific implementation, in the gating transistor arrangement area, the conductive pattern on the third metal layer can be a light shielding pattern, and the light shielding pattern is in a floating state, so as to protect the active pattern of each gating transistor from light emitting by the backlight.

In FIG. 42, the one labeled ZX is a light shielding pattern. In a specific implementation, when the light shielding pattern ZX is electrically connected to the gate electrode formed in the first metal layer, the light shielding pattern ZX is multiplexed as the bottom gate electrode of the gating transistor.

In one embodiment of the array substrate shown in FIGS. 41 to 46, the light shielding pattern ZX may also be in a floating state, which can reduce the load of the gating control signal and facilitate the improvement of the charging capacity of the gating transistor.

In a specific implementation, the light shielding pattern included in the third metal layer can also be set to be in a floating state in the pixel area, while in the GOA area (the GOA area is the area where the driving circuit is set) and the gating transistor arrangement area, the light shielding pattern included in the third metal layer can be connected to the gate signal.

In one embodiment of the present disclosure, the peripheral area further includes an integrated circuit arrangement area arranged in the fan-out area away from the display area;
The array substrate comprises a driving integrated circuit arranged in the integrated circuit arrangement area and a plurality of gating control signal supply lines;
The mth gating control signal supply line is electrically connected to the driving integrated circuit and the mth gating control line respectively, and is configured to receive the mth gating control signal from the driving integrated circuit and provide the mth gating control signal to the mth gating control line;
m is a positive integer less than or equal to M.

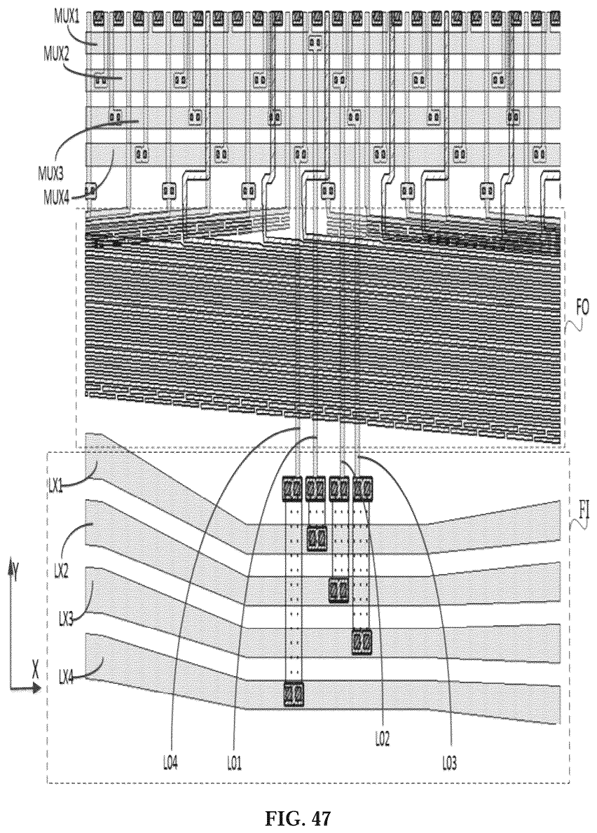

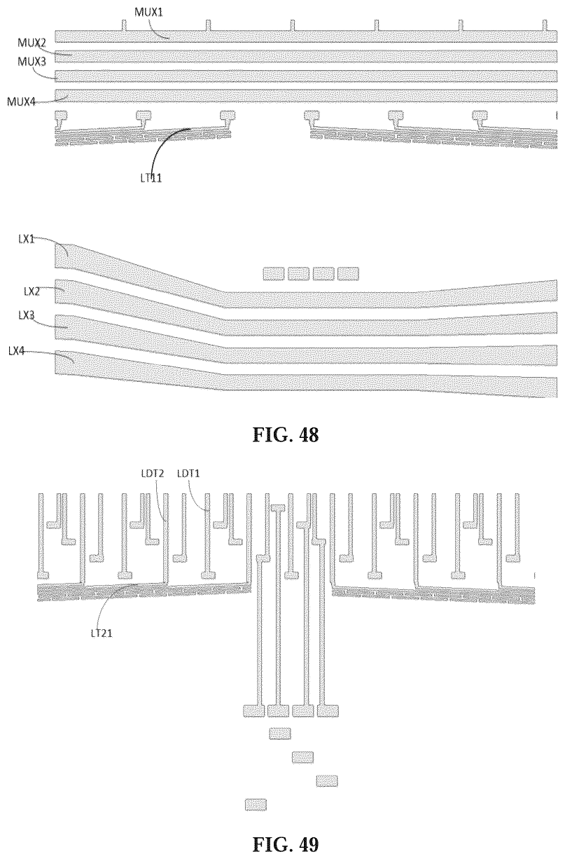

As shown in FIG. 47, the area labeled FO is a fan-out area, and the area labeled FI is an integrated circuit arrangement area;
In FIG. 47, the line labeled LX1 is a first gating control signal supply line, the line labeled LX2 is a second gating control signal supply line, the line labeled LX3 is a third gating control signal supply line, and the line labeled LX4 is a fourth gating control signal supply line;
LX1, LX2, LX3 and LX4 are all arranged in the integrated circuit arrangement area FI;
In FIG. 47, MUX1 is the first gating control line, MUX2 is the second gating control line, MUX3 is the third gating control line, and MUX4 is the fourth gating control line;
The first gating connection line is labeled L01, the second gating connection line is labeled L02, the third gating connection line is labeled L03, and the fourth gating connection line is labeled L04;
MUX1 is electrically connected to LX1 through L01; MUX2 is electrically connected to LX1 through L02; MUX3 is electrically connected to LX3 through L03; and MUX4 is electrically connected to LX4 through L04.

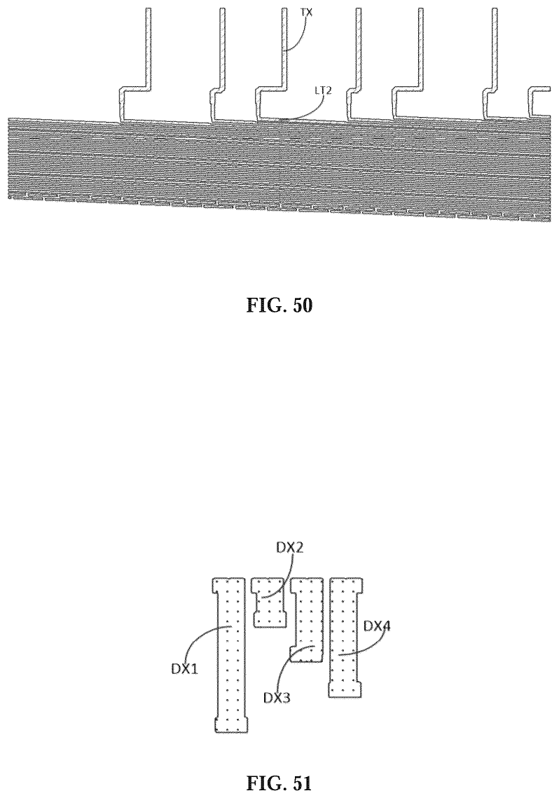

FIG. 48 is a layout diagram of the first metal layer in FIG. 47, FIG. 49 is a layout diagram of the second metal layer in FIG. 47, FIG. 50 is a layout diagram of the sixth metal layer in FIG. 47, and FIG. 51 is a layout diagram of the fourth metal layer in FIG. 47.

In one embodiment of the present disclosure, the peripheral area further includes an integrated circuit arrangement area arranged in the fan-out area away from the display area; the array substrate includes a driving integrated circuit arranged in the integrated circuit arrangement area;
The array substrate includes a touch signal line arranged in the display area;
The data voltage supply line is electrically connected to the driving integrated circuit through a first connection line arranged in the fan-out area, and is configured to receive the data voltage provided by the driving integrated circuit;
The touch signal line is electrically connected to the driving integrated circuit via a second connecting line arranged in the fan-out area, and is configured to receive a touch sensing signal provided by the driving integrated circuit.

As shown in FIG. 50, the line labeled TX is a touch signal line;
As shown in FIG. 48 and FIG. 49, LDT1 is a first data voltage supply line, LDT2 is a second data voltage supply line; LT11 is a first first connection line, and LT21 is a second first connection line;
Both LDT1 and LDT2 are formed in the second metal layer;
LDT1 is electrically connected to the driving integrated circuit through a first first connection line LT11 formed in the first metal layer;
LDT2 is electrically connected to the driving integrated circuit through a second first connection line LT21 formed in the second metal layer;
As shown in FIGS. 47 to 51, the orthographic projection of LT11 on the base substrate at least partially overlaps the orthographic projection of LT21 on the base substrate, and the data voltage supply line is electrically connected to the driving integrated circuit through a connecting line formed on the first metal layer and a connecting line formed on the second metal layer, to save space.

As shown in FIG. 50, the touch signal line TX is electrically connected to the driving integrated circuit via a second connection line LT2 arranged in the fan-out area, and is configured to receive a touch sensing signal provided by the driving integrated circuit.

In FIG. 51, the first conductive line is labeled DX1, the second conductive line is labeled DX2, the third conductive line is labeled DX3, and the fourth conductive line is labeled DX4.

Optionally, the array substrate further includes a sixth metal layer;
The second connecting line is formed in the sixth metal layer.

During specific implementation, the second connection line may be arranged in the sixth metal layer.

Optionally, a part of the first connection lines are formed in the first metal layer, and another part of the first connection lines are formed in the second metal layer.

In one embodiment of the present disclosure, the array substrate further includes a third metal layer; the third metal layer is arranged on a side of the semiconductor layer close to the base substrate;
A part of the first connection line are formed in the first metal layer, another part of the first connection lines are formed in the second metal layer, and another part of the first connection lines are formed in the third metal layer.

In a specific implementation, a part of the first connection lines can be set to be formed in the first metal layer, a part of the first connection lines can be set to be formed in the second metal layer, and a part of the connection lines can be set to be formed in the third metal layer. The orthographic projection of the first connection lines set in the first metal layer on the base substrate, the orthographic projection of the second connection lines set in the second metal layer on the base substrate, and the orthographic projection of the third connection lines set in the third metal layer on the base substrate can at least partially overlap, to save space.

In one embodiment of the present disclosure, the array substrate further includes a touch signal line;
The touch signal line is formed on the second metal layer;
The array substrate further includes a fourth metal layer, a fifth metal layer and a sixth metal layer;
The sixth metal layer is arranged on a side of the second metal layer away from the base substrate, and the fifth metal layer is arranged between the second metal layer and the sixth metal layer;
The touch signal line is electrically connected to the second conductive pattern formed on the fourth metal layer through the sixth via hole; the second conductive pattern is electrically connected to the common electrode formed on the fifth metal layer.

In a specific implementation, the array substrate may not be provided with a sixth metal layer, and the touch signal line may be set to be formed on the second metal layer, and the touch signal line is electrically connected to the second conductive pattern formed on the fourth metal layer through the sixth via hole, and the second conductive pattern is electrically connected to the common electrode formed on the fifth metal layer.

In one embodiment of the present disclosure, when the array substrate is not provided with the sixth metal layer, a 9-mask process is adopted, that is, a light shielding metal layer, a semiconductor layer, a gate metal layer, an interlayer dielectric layer, a source-drain metal layer, an organic film layer, a common electrode layer, a passivation layer and a pixel electrode layer are sequentially provided on the base substrate.

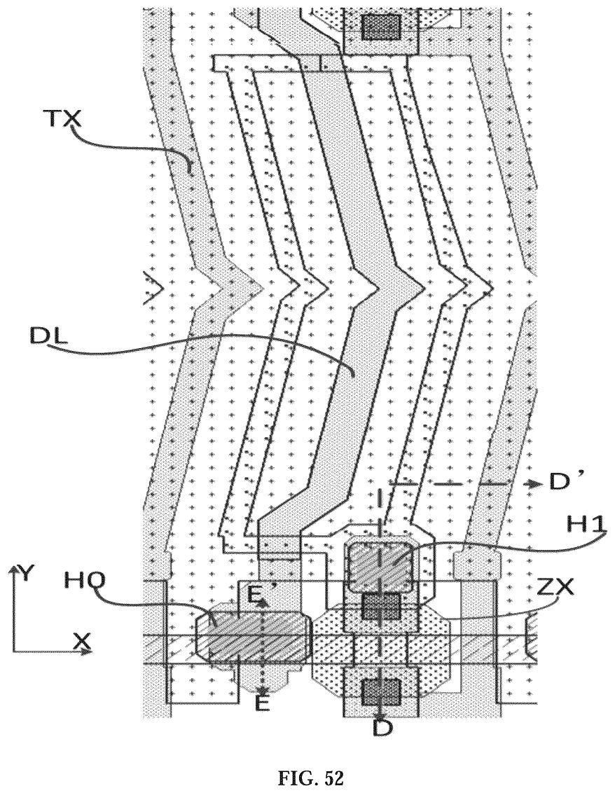

FIG. 52 is a plan layout diagram of a part of array substrate according to at least one embodiment of the present disclosure.

In FIG. 52, the one labeled H1 is the first via hole, the one labeled H0 is the TX via hole, the one labeled TX is the touch signal line, and the one labeled DL is the data line.

The area of the orthographic projection of the first via hole H1 on the base substrate is greater than or equal to 6 μm×7 μm and less than or equal to 8 μm×10 μm. For example, the area of the orthographic projection of the first via hole H1 on the base substrate may be 7 μm×8.5 μm.

As shown in FIGS. 52 to 58, TX via hole H0 is a half-lapped hole, half of which overlaps the fifth metal layer and the other half overlaps the second metal layer. The conductive pattern on the fourth metal layer is connected to the first metal layer through the via on the left and to the second metal layer through the via on the right. The touch signal line formed on the second metal layer is indirectly electrically connected to the common electrode formed on the fifth metal layer through the conductive pattern on the fourth metal layer.

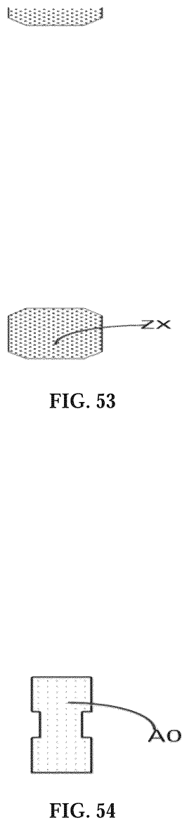

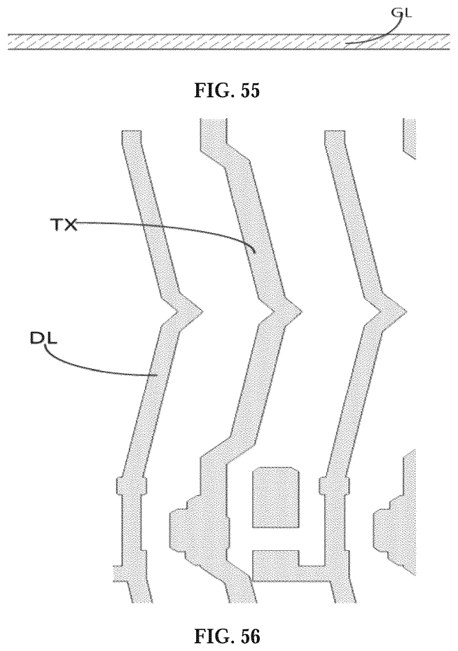

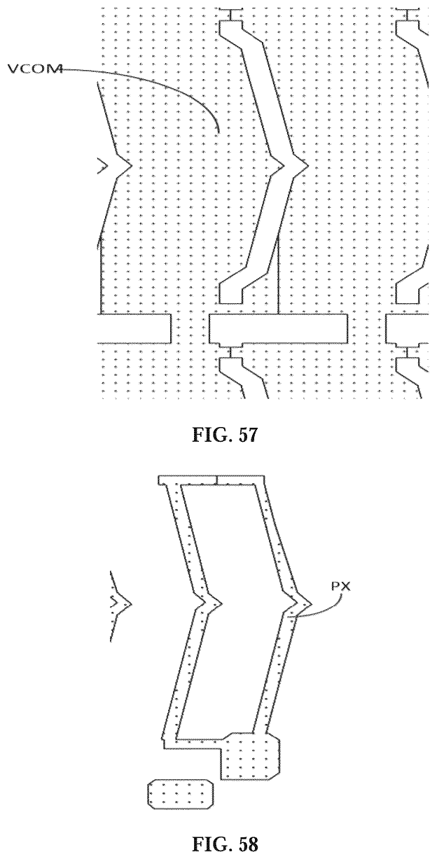

FIG. 53 is a layout diagram of the third metal layer in FIG. 52, FIG. 54 is a layout diagram of the semiconductor layer in FIG. 52, FIG. 55 is a layout diagram of the first metal layer in FIG. 52, FIG. 56 is a layout diagram of the second metal layer in FIG. 52, FIG. 57 is a layout diagram of the fifth metal layer in FIG. 52, and FIG. 58 is a layout diagram of the fourth metal layer in FIG. 52.

In FIG. 53, the one labeled ZX is a light shielding pattern; in FIG. 54, the one labeled A0 is an active pattern; in FIG. 55, the one labeled GL is a gate line; in FIG. 56, the one labeled DL is a data line, and the one labeled TX is a touch signal line; in FIG. 57, the one labeled VCOM is a common electrode; in FIG. 58, the one labeled PX is a pixel electrode.

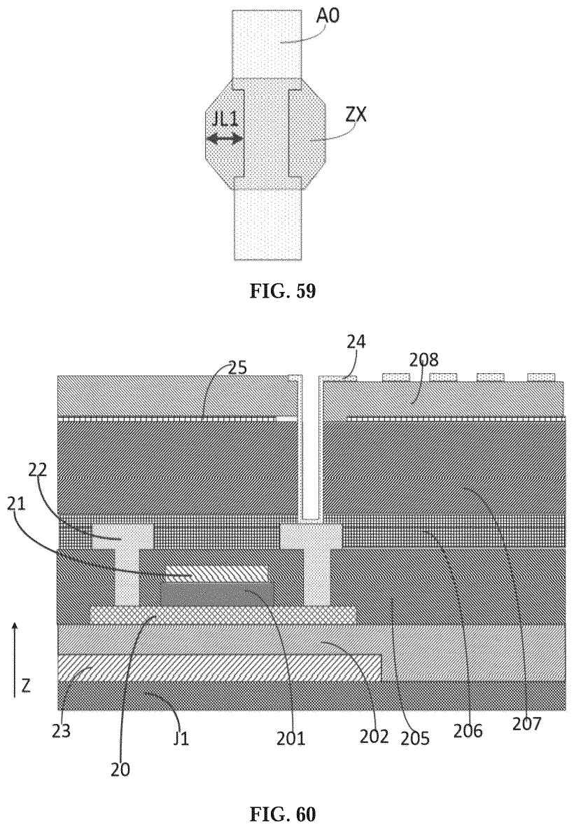

FIG. 59 is a superimposed diagram of the third metal layer shown in FIG. 53 and the semiconductor layer shown in FIG. 54.

As shown in FIG. 59, the active pattern A0 extends along a first direction (the first direction may be a vertical direction), and the longest distance between the edge of the orthographic projection of the light shielding pattern ZX on the base substrate and the edge of the orthographic projection of the active pattern A0 on the base substrate in the horizontal direction is a first distance JL1;
JL1 is greater than the first distance threshold.

FIG. 60 is the D-D′ cross-sectional view of the array substrate according to at least one embodiment of the present disclosure shown in FIG. 52.

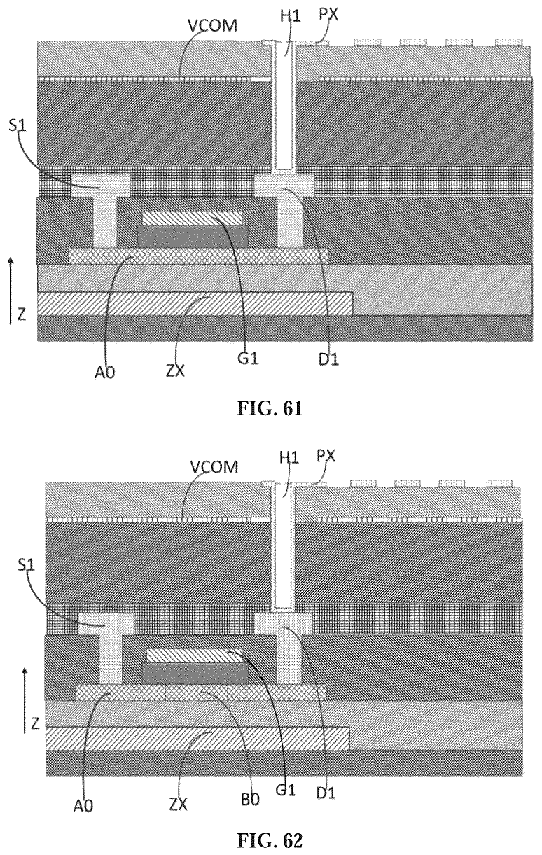

As shown in FIG. 60, the array substrate according to at least one embodiment of the present disclosure includes a first metal layer 21, a second metal layer 22, a semiconductor layer 20, a first insulating layer 201, a third metal layer 23, a second insulating layer 202, a fourth metal layer 24, a fifth metal layer 25, a fifth insulating layer 205, a sixth insulating layer 206, a seventh insulating layer 207 and an eighth insulating layer 208;
The third metal layer 23, the semiconductor layer 20, the first metal layer 21, the second metal layer 22, the fifth metal layer 25 and the fourth metal layer 24 are arranged in sequence along a direction away from the base substrate J1;
A second insulating layer 202 is arranged between the third metal layer 23 and the semiconductor layer 20;
A first insulating layer 201 is arranged between the semiconductor layer 20 and the first metal layer 21;
A fifth insulating layer 205 is arranged between the first metal layer 21 and the second metal layer 22;
A sixth insulating layer 206 and a seventh insulating layer 207 are stacked between the second metal layer 22 and the fifth metal layer 25; the sixth insulating layer 206 is arranged between the seventh insulating layer 207 and the second metal layer 22;
An eighth insulating layer 208 is arranged between the fourth metal layer 24 and the fifth metal layer 25;
Among them, the first metal layer 21 may be a second gate metal layer, the second metal layer 22 may be a source-drain metal layer, the first insulating layer 201 may be a second gate insulating layer, the third metal layer 23 may be a light shielding metal layer, and the light shielding metal layer may be multiplexed as the first gate electrode metal layer, the fourth metal layer 24 may be a pixel electrode layer, and the fifth metal layer 25 may be a common electrode layer;
The first insulating layer 201 may be a second gate insulating layer, the second insulating layer 202 may be a first gate insulating layer, the fifth insulating layer 205 may be an interlayer dielectric layer, the sixth insulating layer 206 may be a first passivation layer, the seventh insulating layer 207 may be an organic film layer, and the eighth insulating layer 208 may be a second passivation layer;
As shown in FIG. 61, the switch transistor includes an active pattern A0, a first gate electrode G1, a first electrode S1 and a second electrode D1;
The first gate electrode G1 is formed on the first metal layer 21, the first electrode S1 and the second electrode D1 are formed on the second metal layer 22, and the active pattern A0 is formed on the semiconductor layer 20;
The third metal layer includes a light shielding pattern ZX, and the orthographic projection of the light shielding pattern ZX on the base substrate covers the orthographic projection of the active pattern A0 on the base substrate;
The light shielding pattern ZX can be multiplexed as the second gate electrode of the switch transistor;
The pixel circuit further includes a pixel electrode PX; the pixel electrode PX is formed on the fourth metal layer 24;
The pixel electrode PX is electrically connected to the second electrode D1 through a first via hole H1; the first via hole H1 penetrates the first passivation layer and the organic film layer, that is, the first via hole H1 includes a first sub-via hole penetrating the organic film layer and a second sub-via hole penetrating the first passivation layer;
The display unit further includes a common electrode VCOM, and the common electrode VCOM is formed on the fifth metal layer 25;
As shown in FIG. 62, based on one embodiment of the array substrate shown in FIG. 61, the active pattern A0 may include a semiconductor portion B0.

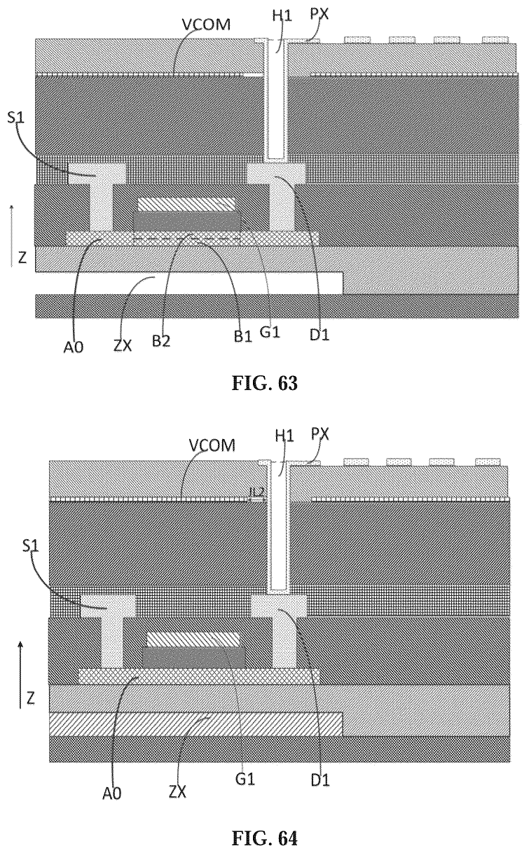

As shown FIG. 63, based on at least one embodiment of the array substrate shown in FIG. 62, the semiconductor portion includes a first semiconductor portion B1 and a second semiconductor portion B2.

As shown in FIG. 64, based on one embodiment of the array substrate shown in FIG. 61, the shortest distance between the orthographic projection of the common electrode VCOM on the base substrate and the edge of the orthographic projection of the first via hole H1 on the base substrate is a second distance JL2;
The second distance JL2 is greater than the second distance threshold.

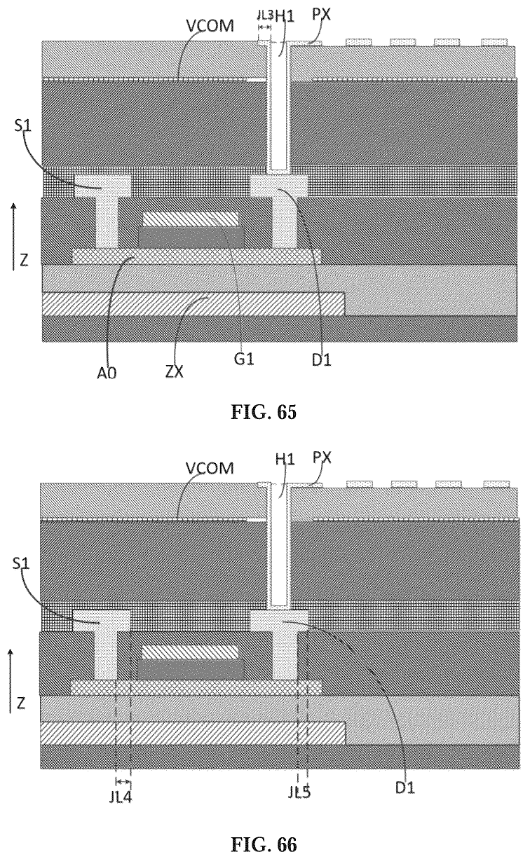

As shown in FIG. 65, based on one embodiment of the array substrate shown in FIG. 61, the shortest distance between the orthographic projection of the pixel electrode PX on the base substrate and the edge of the orthographic projection of the first via hole H1 on the base substrate is a third distance JL3, and the third distance J3 is greater than the third distance threshold.

As shown in FIG. 66, based on one embodiment of the array substrate shown in FIG. 61, the shortest distance between the edge of the orthographic projection of the first electrode S1 on the base substrate and the edge of the orthographic projection of the second via hole H2 on the base substrate is a fourth distance JLA, and the shortest distance between the edge of the orthographic projection of the second electrode D1 on the base substrate and the edge of the orthographic projection of the second via hole H2 on the base substrate is a fifth distance JL5; the fourth distance JL4 is greater than the fourth distance threshold, and the fifth distance JL5 is greater than the fifth distance threshold.

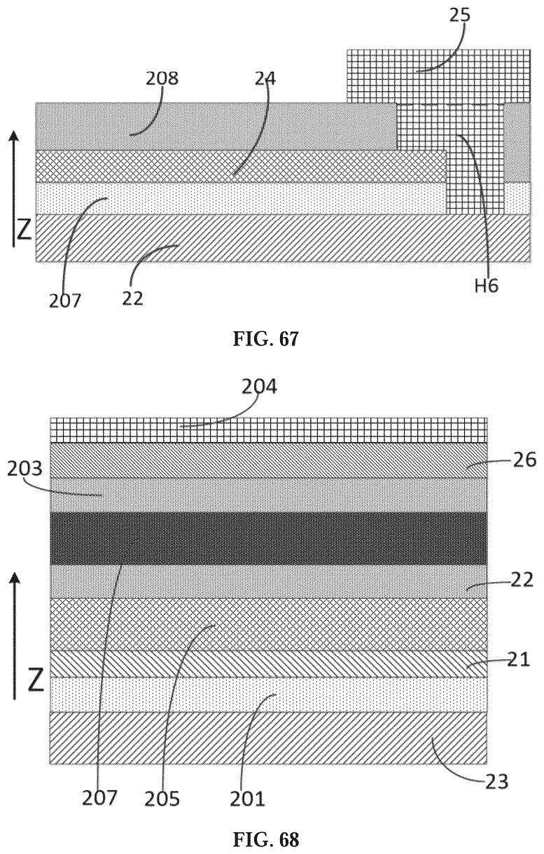

FIG. 67 is the cross-sectional view in E-E in FIG. 52.

In FIG. 67, only the second metal layer 22, the seventh insulating layer 207, the eighth insulating layer 208, the fourth metal layer 24, and the fifth metal layer 25 are drawn;
The fourth metal layer 24 is electrically connected to the second metal layer 22 and the fifth metal layer 25 through via holes, so that the touch signal line formed on the second metal layer 22 is electrically connected to the common electrode formed on the fifth metal layer 25;
In FIG. 67, the via hole labeled H6 is the sixth via hole.

In one embodiment of the present disclosure, the data voltage supply line is electrically connected to the driving integrated circuit through a first connection line arranged in the fan-out area; the touch signal line is electrically connected to the driving integrated circuit through a second connection line arranged in the fan-out area; the array substrate further includes a third metal layer; the third metal layer is arranged on a side of the semiconductor layer close to the base substrate; the second connection line is formed in the second metal layer;
A part of the first connection line is formed in the first metal layer, and another part of the first connection line is formed in the third metal layer.

In a specific implementation, a part of the first connection line can be formed in the first metal layer, and another part of the first connection line can be formed in the third metal layer. The orthographic projection of the first connection line formed in the first metal layer on the base substrate at least partially overlaps the orthographic projection of the first connection line formed in the third metal layer on the base substrate, to save space.

In a specific implementation, when the array substrate includes a sixth metal layer, four layers of metal wiring line can be used in the fan-out area. The four layers of metal can be: a third metal layer, a first metal layer, a second metal layer and a sixth metal layer. Through four-layer metal stacking wiring line, the lower frame can be further reduced.

FIG. 68 is a cross-sectional view of the four metal layers in the fan-out area.

In FIGS. 68, 23 is the third metal layer, 21 is the first metal layer, 22 is the second metal layer, and 26 is the sixth metal layer;
201 is the first insulating layer, 205 is the fifth insulating layer, 207 is the seventh insulating layer, 203 is the third insulating layer, and 208 is the eighth insulating layer.

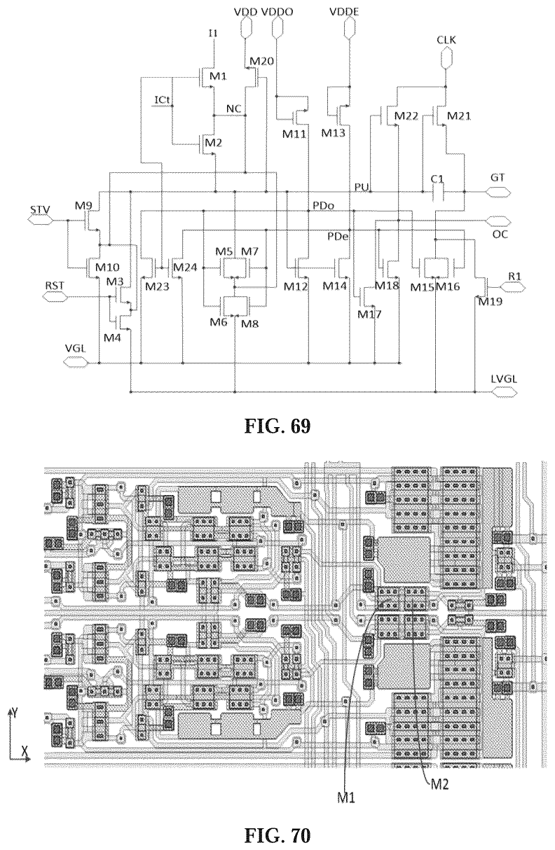

FIG. 69 is a circuit diagram of a driving circuit.

The difference between at least one embodiment of the driving circuit shown in FIG. 69 and at least one embodiment of the driving circuit shown in FIG. 31 is as follows: the input control terminal ICt is not connected to the input terminal I1;
ICt is electrically connected to the carry signal output terminal of the adjacent previous n stages of driving circuits, and I1 is electrically connected to the driving signal output terminal of the adjacent previous n stages of driving circuits.

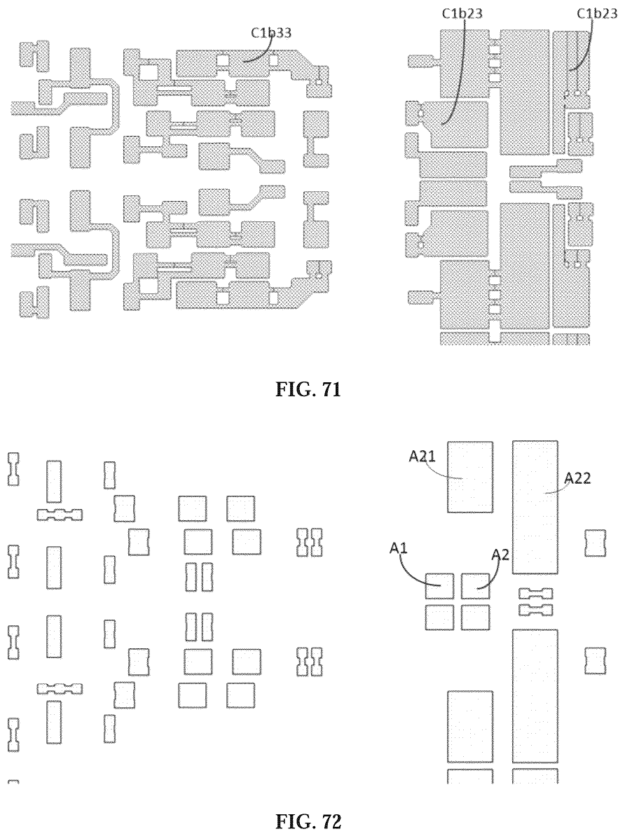

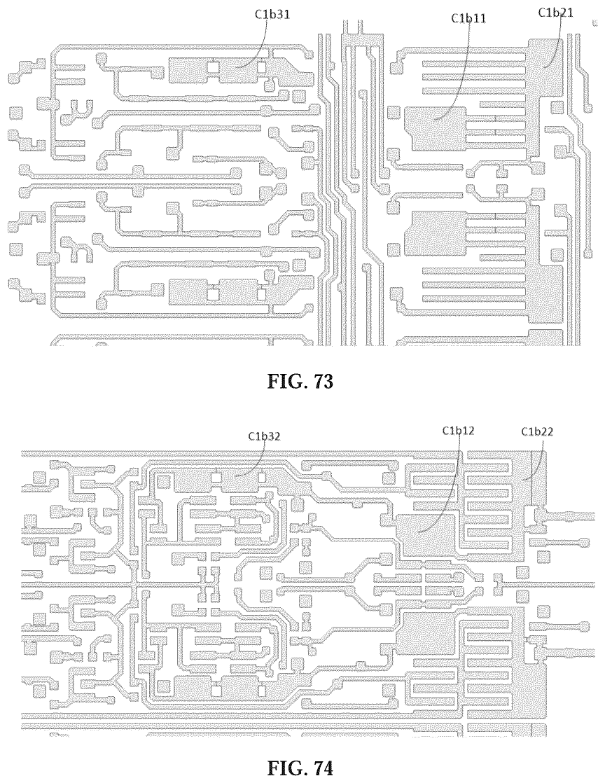

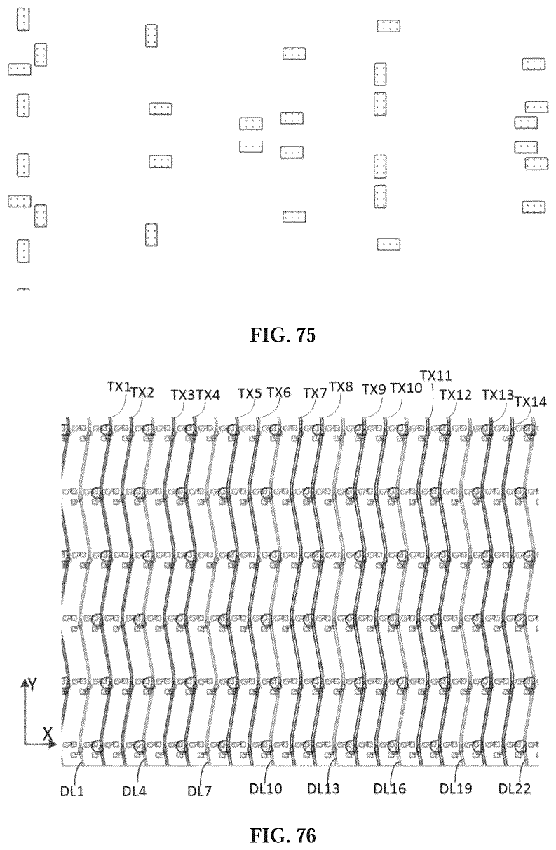

FIG. 70 is the layout diagram of the driving circuit shown in FIG. 69, FIG. 71 is a layout diagram of the third metal layer in FIG. 70, FIG. 72 is a layout diagram of the semiconductor layer in FIG. 70, FIG. 73 is a layout diagram of the first metal layer in FIG. 70, FIG. 74 is a layout diagram of the second metal layer in FIG. 70, and FIG. 75 is a layout diagram of the fourth metal layer in FIG. 70.

In FIG. 75, each pattern is a conductive pattern.

In FIG. 72, A1 is an active pattern of M1, A2 is an active pattern of M2, A21 is an active pattern of M21, and A22 is an active pattern of M22.

An array substrate according to one embodiment of the present disclosure further includes a data line formed in the second metal layer;
The array substrate comprises 3a data lines and 2a touch signal lines; a is a positive integer;
The two touch signal lines correspond to the three data lines, and an orthographic projection of the touch signal line on the base substrate at least partially overlaps an orthographic projection of one of the three data lines on the base substrate.

In a specific implementation, two touch signal lines may be provided corresponding to three data lines, and the orthographic projection of the touch signal line on the base substrate at least partially overlaps the orthographic projection of the data line on the base substrate, which is beneficial to reducing the capacitance of the touch signal line.

As shown in FIG. 76, TX1 is the first touch signal line, TX2 is the second touch signal line, TX3 is the third touch signal line, TX4 is the fourth touch signal line, TX5 is the fifth touch signal line, TX6 is the sixth touch signal line, TX7 is the seventh touch signal line, TX8 is the eighth touch signal line, TX9 is the ninth touch signal line, TX10 is the tenth touch signal line, TX11 is the eleventh touch signal line, TX12 is the twelfth touch signal line, TX13 is the thirteenth touch signal line, and TX14 is the fourteenth touch signal line;
DL1 is the first data line, DL4 is the fourth data line, DL7 is the seventh data line, DL10 is the tenth data line, DL13 is the thirteenth data line, DL 16 is the sixteenth data line, DL 19 is the nineteenth data line, and DL22 is the twenty-second data line;
A second data line is arranged below the first touch signal line TX1, a third data line is arranged below the second touch signal line TX2, a fifth data line is arranged below the third touch signal line TX3, a sixth data line is arranged below the fourth touch signal line TX4, an eighth data line is arranged below the fifth touch signal line TX5, a ninth data line is arranged below the sixth touch signal line TX6, an eleventh data line is arranged below the seventh touch signal line TX7, a twelfth data line is arranged below the eighth touch signal line TX8, a fourteenth data line is arranged below the ninth touch signal line TX9, a fifteenth data line is arranged below the tenth touch signal line TX10, a seventeenth data line is arranged below the eleventh touch signal line TX11, an eighteenth data line is arranged below the twelfth touch signal line TX12, a twentieth data line is arranged below the thirteenth touch signal line TX13, and a twenty-first data line is arranged below the fourteenth touch signal line TX14.

The array substrate according to at least one embodiment of the present disclosure further includes a data line formed in the second metal layer;
The array substrate comprises 3a data lines and a touch signal line; a is a positive integer;
One touch signal line corresponds to three data lines, and an orthographic projection of the touch signal line on the base substrate at least partially overlaps an orthographic projection of one of the three data lines on the base substrate.

In a specific implementation, one or two touch signal lines may be provided corresponding to three data lines, and the orthographic projection of the touch signal line on the base substrate at least partially overlaps the orthographic projection of the data line on the base substrate, which is beneficial to reducing the capacitance of the touch signal line.

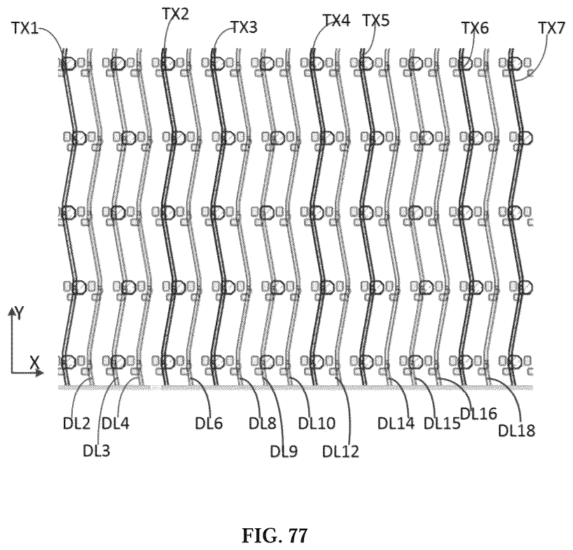

As shown in FIG. 77, the first touch signal line is labeled TX1, the second touch signal line is labeled TX2, the third touch signal line is labeled TX3, the fourth touch signal line is labeled TX4, the fifth touch signal line is labeled TX5, the sixth touch signal line is labeled TX6, and the seventh touch signal line is labeled TX7;
The second data line is labeled DL2, the third data line is labeled DL3, the fourth data line is labeled DL4, the sixth data line is labeled DL6, the eighth data line is labeled DL8, the ninth data line is labeled DL9, the tenth data line is labeled DL10, the twelfth data line is labeled DL12, the fourteenth data line is labeled DL14, the fifteenth data line is labeled DL15, the sixteenth data line is labeled DL16, and the eighteenth data line is labeled DL18;
A first data line is arranged under TX1, a fifth data line is arranged under TX2, a seventh data line is arranged under TX3, an eleventh data line is arranged under TX4, a thirteenth data line is arranged under TX5, a seventeenth data line is arranged under TX6, and a nineteenth data line is arranged under TX7.

The display device described in the embodiment of the present disclosure includes the above-mentioned array substrate.

The above descriptions are implementations of the present disclosure. It should be pointed out that those skilled in the art can make some improvements and modifications without departing from the principle of the present disclosure. These improvements and modifications shall also fall within the scope of the present disclosure.

1. An array substrate, comprising a plurality of first wiring lines and a plurality of second wiring lines arranged on a base substrate, wherein the first wiring lines and the second wiring lines intersect each other to define a plurality of pixel areas, each of the pixel areas comprises a transistor, a first electrode, a second electrode, a first via hole and a second via hole; an orthographic projection of the first via hole on the base substrate at least partially overlaps an orthographic projection of the first electrode on the base substrate, and an orthographic projection of the second via hole on the base substrate at least partially overlaps the orthographic projection of the first electrode on the base substrate;
the orthographic projection of the first via hole on the base substrate does not overlap an orthographic projection of the second electrode on the base substrate, and the orthographic projection of the second via hole on the base substrate does not overlap the orthographic projection of the second electrode on the base substrate.

2. The array substrate according to claim 1, wherein the first via hole and the second via hole are located in a same pixel area;
another pixel area adjacent to the pixel area includes a third via hole;
the orthographic projection of the second via hole on the base substrate and an orthographic projection of the third via hole on the base substrate are located on opposite sides of an orthographic projection of the first wiring line on the base substrate.

3. The array substrate according to claim 1, wherein the transistor comprises an active pattern;
the orthographic projection of the second via hole on the base substrate at least partially overlaps an orthographic projection of a first conductor portion included in the active pattern on the base substrate; the second via hole is configured to electrically connect the first electrode of the transistor to the first conductor portion of the active pattern;
a part of the first electrode falls into the first via hole, and the first via hole is configured to electrically connect the first electrode and the first conductor portion included in the active pattern.

4. The array substrate according to claim 2, wherein an orthographic projection of the third via on the base substrate at least partially overlaps an orthographic projection of a second conductor portion included in the active pattern on the base substrate; the third via hole is configured to electrically connect the second electrode of the transistor to the second conductor portion of the active pattern.

5. The array substrate according to claim 1, wherein, along a first direction, a minimum distance between the orthographic projection of the first via hole on the base substrate and the orthographic projection of the first wiring line on the base substrate is smaller than a minimum distance between the orthographic projection of the second via hole on the base substrate and the orthographic projection of the first wiring line on the base substrate.

6. The array substrate according to claim 1, wherein the active pattern is in a dumbbell shape; and an angle between the orthographic projection of the active pattern on the base substrate and the orthographic projection of the first wiring line on the base substrate is greater than or equal to 85 degrees and less than or equal to 95 degrees.

7. The array substrate according to claim 1, wherein the second wiring line includes a second wiring line body, a first auxiliary portion, and a second auxiliary portion;
the first auxiliary portion is electrically connected to the second wiring line body, and the second auxiliary portion is in a floating state;
the first auxiliary portion is electrically connected to the second conductor portion included in the active pattern, and the second auxiliary portion is electrically connected to the first electrode.

8. The array substrate according to claim 1, wherein the array substrate includes 3a second wiring lines and 2a third wiring lines; a is a positive integer;
two third wiring lines correspond to three second wiring lines, and the orthographic projection of the third wiring lines on the base substrate at least partially overlaps an orthographic projection of one of the three second wiring lines on the base substrate.

9. The array substrate according to claim 1, wherein the array substrate includes 3a second wiring lines and a third wiring lines; a is a positive integer;
one of the third wiring lines corresponds to three second wiring lines, and an orthographic projection of the third wiring line on the base substrate at least partially overlaps an orthographic projection of one of the three second wiring lines on the base substrate.

10. The array substrate according to claim 1, wherein the array substrate further comprises a third wiring line;
the third wiring line includes a signal line body portion and a connection portion electrically connected to each other;
an orthographic projection of the connection portion on the base substrate at least partially overlaps the orthographic projection of the second via hole on the base-substrate substrate;
wherein the array substrate further includes a light shielding pattern; the light shielding pattern and the third wiring line are arranged in different layers;
an orthographic projection of the connection portion on the base substrate at least partially overlaps an orthographic projection of the light shielding pattern on the base substrate.

11. (canceled)

12. The array substrate according to claim 1, wherein the array substrate further comprises a light shielding pattern;
an orthographic projection of the light shielding pattern on the base substrate covers an orthographic projection of a conductor portion of an active pattern of the transistor on the base substrate.

13. The array substrate according to claim 1, wherein the array substrate includes a first metal layer, a second metal layer, a semiconductor layer and a first insulating layer;
the transistor comprises an active pattern, a first gate electrode, a first electrode and a second electrode;
the first gate electrode is formed on the first metal layer, the first electrode and the second electrode are formed on the second metal layer, and the active pattern is located in the semiconductor layer;
the first insulating layer is arranged between the first metal layer and the semiconductor layer;
a thickness of the first insulating layer is less than a first thickness threshold; the first thickness threshold is greater than or equal to 800 angstroms and less than or equal to 2000 angstroms;
the first metal layer is arranged on a side of the semiconductor layer away from the base substrate.

14. The array substrate according to claim 13, wherein the thickness of the first insulating layer is greater than or equal to 500 angstroms and less than or equal to 2000 angstroms;
or
wherein the active pattern includes a semiconductor portion; the semiconductor portion includes a first semiconductor portion and a second semiconductor portion which are stacked;
the first semiconductor portion is arranged between the second semiconductor portion and the base substrate, and the first semiconductor portion and the second semiconductor portion are made of semiconductor materials with different carrier mobilities; or
wherein the array substrate further comprises a third metal laver and a second insulating layer;
the third metal layer is arranged between the semiconductor layer and the base substrate, and the second insulating layer is arranged between the semiconductor layer and the third metal laver;
the third metal layer includes a light shielding pattern, and an orthographic projection of the light shielding pattern on the base substrate covers an orthographic projection of a semiconductor portion in the active pattern on the base substrate,
wherein the active pattern extends along a first direction;
a farthest distance between an edge of the orthographic projection of the light shielding pattern on the base substrate and an edge of the orthographic projection of the active pattern on the base substrate along a second direction is greater than a first distance threshold;
the first distance threshold is greater than or equal to 4 μm; and the first direction intersects with the second direction; or
wherein the light shielding pattern is multiplexed as a second gate electrode of the switch transistor.

15.-18. (canceled)

19. The array substrate according to claim 13, wherein the array substrate further comprises a fourth metal layer; the first electrode is formed on the fourth metal layer; the fourth metal layer is arranged on a side of the second metal layer away from the base substrate;
the first electrode is electrically connected to the second electrode of the transistor through a first via hole;
an area of an orthographic projection of the first via hole on the base substrate is greater than or equal to 6 μm×7 μm and less than or equal to 8 μm×10 μm.

20. The array substrate according to claim 19, wherein the array substrate further includes a fifth metal layer, the second electrode is formed on the fifth metal layer, the fifth metal layer is arranged between the fourth metal layer and the second metal layer;
a shortest distance between the orthographic projection of the second electrode on the base substrate and the edge of the orthographic projection of the first via hole on the base substrate is greater than a second distance threshold;
the second distance threshold is greater than 2 μm;
or
wherein the shortest distance between the orthographic projection of the first electrode on the base substrate and an edge of the orthographic projection of the first via hole on the base substrate is greater than a third distance threshold;
the third distance threshold is greater than or equal to 1.6 μm.

21. (canceled)

22. The array substrate according to claim 13, wherein the array substrate further comprises a fifth metal layer and a sixth metal layer, the fifth metal layer is arranged on a side of the second metal layer away from the base substrate, and the sixth metal layer is arranged on a side of the fifth metal layer away from the base substrate;
the array substrate comprises a third wiring line;
the third wiring line is formed on the sixth metal layer, and the second electrode is formed on the fifth metal layer;
the array substrate further includes a fourth metal layer, a third insulating layer arranged between the sixth metal layer and the fifth metal layer, and a fourth insulating layer arranged between the sixth metal layer and the fourth metal layer; the fourth metal layer is arranged on a side of the sixth metal layer away from the base substrate;
the array substrate comprises a first conductive pattern formed on the fourth metal layer;
the first conductive pattern is electrically connected to the third wiring line through the fourth via hole, and the first conductive pattern is electrically connected to the second electrode through the fourth via hole and the fifth via hole, so that the third wiring line is electrically connected to the second electrode;
the fourth via hole is a via hole penetrating the fourth insulating layer, and the fifth via hole is a via hole penetrating the third insulating layer;
an area of an orthographic projection of the fourth via hole on the base substrate is greater than or equal to 3 μm×6 μm and less than or equal to 5 μm×8 μm.

23. The array substrate according to claim 13, wherein the array substrate includes a sixth metal layer, the array substrate includes a third wiring line, and the third wiring line is formed in the sixth metal layer;
the third wiring line includes a signal line body portion and a connection portion that are interconnected;
the orthographic projection of the connection portion on the base substrate covers an orthographic projection of a spacer on the base substrate, and the connection portion is configured to support the spacer;
the array substrate is included in a display device, and the display device includes a color filter substrate, the spacer is arranged between the color filter substrate and the array substrate.

24. The array substrate according to claim 13, further comprising a driving module arranged on the base substrate; wherein the driving module is arranged in a peripheral area;
the driving module includes a plurality of stages of driving circuits; the driving circuit is configured to provide a driving signal for the pixel circuit;
the driving circuit includes an input circuit, a reset circuit and a first node control circuit;
the input circuit is electrically connected to an input control terminal, an input terminal and a first node respectively, and is configured to write an input signal provided by the input terminal into the first node under the control of an input control signal provided by the input control terminal;
the reset circuit is electrically connected to a reset line, the first node and a first voltage line respectively, and is configured to control the connection between the first node and the first voltage line under the control of a reset signal provided by the reset line;
the first node control circuit is electrically connected to a first second node, a second second node, a second voltage line and the first node, respectively, and is configured to control the connection between the first node and the second voltage line under the control of a potential of the first second node, and to control the connection between the first node and the second voltage line under the control of a potential of the second second node.

25. The array substrate according to claim 24, wherein the driving circuit further comprises a frame reset circuit;
the frame reset circuit is electrically connected to a frame reset line, the first node and the second voltage line respectively, and is configured to control the connection between the first node and the second voltage line under the control of a frame reset signal provided by the frame reset line;
or
wherein the input circuit comprises a first transistor and a second transistor;
a gate electrode of the first transistor and a gate electrode of the second transistor are electrically connected to the input control terminal, a first electrode of the first transistor is electrically connected to the input terminal, and a second electrode of the first transistor is electrically connected to the control node;
a first electrode of the second transistor is electrically connected to the control node, and a second electrode of the second transistor is electrically connected to the first node,
wherein the driving circuit further comprises a control circuit;
the control circuit is electrically connected to the control node, the first node and the third voltage line respectively, and is configured to control the connection between the control node and the third voltage line under the control of the potential of the first node.

26-42. (canceled)

43. A display device comprising the array substrate according to claim 1.
